(19) United States
(12) Patent Application Publication
(10) Pub. No.: US 2026/0182023 A1
(43) Pub. Date: Jun. 25, 2026

(54) INTEGRATED CIRCUIT INCLUDING MULTI-HEIGHT CELL

(71) Applicant: Samsung Electronics Co., Ltd., Suwon-si (KR)

(72) Inventors: Ahreum Kim, Suwon si (KR); Byungsu Kim, Suwon si (KR)

(21) Appl. No.: 19/409,075

(22) Filed: Dec. 4, 2025

(30) Foreign Application Priority Data
Dec. 24, 2024 (KR) 10-2024-0196218

(51) Int. Cl. H10D 84/90; H10D 89/10

(52) U.S. Cl. CPC H10D 84/924; H10D 84/953; H10D 89/10

(57) ABSTRACT

An integrated circuit includes a multi-height cell, a plurality of cells, and at least one filler cell. The multi-height cell includes at least one normal active pattern having a first width and at least one wide active pattern having a second width greater than the first width, where the at least one normal active pattern and the at least one wide active pattern respectively extend in a first direction. The plurality of cells are adjacent to one another in a second direction crossing the first direction, where each of the plurality of cells includes at least one active pattern having the first width. The at least one filler cell is arranged between an adjacent cell of the plurality of cells and the multi-height cell in the first direction.

### CROSS-REFERENCE TO RELATED APPLICATION

This application is based on and claims priority under 35 U.S.C. § 119 to Korean Patent Application No. 10-2024-0196218, filed on Dec. 24, 2024, in the Korean Intellectual Property office, the disclosure of which is incorporated by reference herein in its entirety.

### BACKGROUND

As electronic products become more miniaturized, multi-functional, and of high-performance, high-capacity integrated circuit devices may be desired, and to provide high-capacity integrated circuit devices, an increased degree of integration may be desired.

### SUMMARY

In some examples, when the cell height decreases, an area of the integrated circuit may be reduced, but sizes of an active region, a contact, and/or a via may also be reduced, and accordingly, cell performance may be reduced. Thus, to achieve the functions and operation speed required for the integrated circuit devices, it may be desired to design the integrated circuit devices considering the degree of integration and performance.

Implementations of the present disclosure provides an integrated circuit including a multi-height cell including a normal active pattern and a wide active pattern having different widths from each other.

An aspect of the present disclosure provides an integrated circuit including a multi-height cell including at least one normal active pattern having a first width and at least one wide active pattern having a second width greater than the first width, where the at least one normal active pattern and the at least one wide active pattern respectively extend in a first direction, a plurality of cells adjacent to each other in a second direction crossing the first direction, where each of the plurality of cells includes at least one active pattern having the first width, and at least one filler cell arranged between the plurality of cells and the multi-height cell, in the first direction.

In addition, another aspect of the present disclosure provides an integrated circuit including a multi-height cell, where the multi-height cell includes at least one normal active pattern extending in a first direction, having a first length in the first direction, and having a first width in a second direction crossing the first direction, at least one wide active pattern extending in the first direction, having a second length less than the first length in the first direction, and having a second width greater than the first width in the second direction, at least one gate electrode extending in the second direction above the at least one normal active pattern and the at least one wide active pattern, at least one dummy gate electrode extending in the second direction, and a filler overlapped by the at least one dummy gate electrode.

Furthermore, another aspect of the present disclosure provides an integrated circuit including a multi-height cell, and a plurality of cells adjacent to the multi-height cell in a first direction, and adjacent to each other in a second direction, where the multi-height cell includes at least one normal active pattern extending in the first direction, and having a first width, and at least wide active pattern extending in the first direction, and having a second width greater than the first width, and where each of the plurality of cells includes at least one active pattern extending in the first direction, and having the first width.

### BRIEF DESCRIPTION OF THE DRAWINGS

FIG. 1 is a layout of an example of an integrated circuit.

FIG. 2 is a layout of an example of an integrated circuit.

FIG. 3A is an example of a cross-sectional view of the integrated circuit taken along line X1-X1′ in FIG. 2, FIG. 3B is an example of a cross-sectional view thereof taken along line X2-X2′ in FIG. 2, and FIG. 3C is an example of a cross-sectional view thereof taken along line Y1-Y1′ in FIG. 2.

FIG. 4 is a block diagram of an example of an integrated circuit.

FIGS. 5 to 27 respectively are layouts of examples of integrated circuits.

FIGS. 28A through 28D respectively illustrate examples of devices.

FIG. 29 is a flowchart of an example method of manufacturing an integrated circuit.

### DETAILED DESCRIPTION

Hereinafter, implementations are described in detail with reference to the accompanying drawings.

In some examples, an X-axis direction may be referred to as a first direction, a Y-axis direction may be referred to as a second direction, and a Z-axis direction may be referred to as a vertical direction. A plane formed by the X-axis and the Y-axis may be referred to as a horizontal plane, components arranged in the +Z-axis direction relative to other components may be referred to as being on the other components, and components arranged in the-Z-axis direction relative to other components may be referred to as being under the other components.

An integrated circuit may be designed by placing or arranging a plurality of standard cells. A standard cell may be a unit of a layout of an integrated circuit, and may also be referred to as a “cell” according to some implementations. A standard cell may be designed to include a plurality of transistors for performing a pre-defined function. A standard cell may be registered in a standard cell library after the design and verification of a standard cell is performed in advance, and an integrated circuit may be designed by performing a logical design, placement, and routing of a combination of standard cells by using computer aided design (CAD).

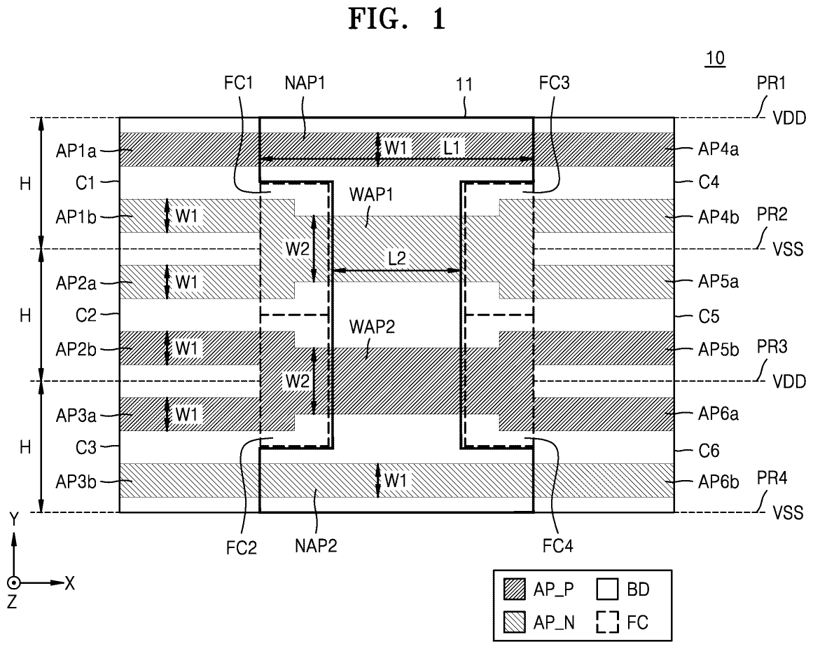

FIG. 1 is a layout of an integrated circuit 10 according to some implementations.

Referring to FIG. 1, the integrated circuit 10 may include a multi-height cell 11, a plurality of cells, for example, first through sixth cells C1 through C6, and a plurality of filler cells, for example, first through fourth filler cells FC1 through FC4. The first and second filler cells FC1 and FC2 may be placed or arranged between the first through third cells C1 through C3 and the multi-height cell 11, and the third and fourth filler cells FC3 and FC4 may be placed or arranged between the multi-height cell 11 and the fourth through sixth cells C4 through C6.

The multi-height cell 11 may be placed or arranged over a plurality of rows, and accordingly, may be referred to as a “multi-row cell”. The multi-height cell 11 may have a cell height corresponding to a multiple of a first cell height H (that is, N×H, in this case, N is a natural integer greater than 2). For example, each of the first through sixth cells C1 through C6 may correspond to a single-height cell having the first cell height H, and the multi-height cell 11 may correspond to a triple-height cell having a cell height corresponding to three times the first cell height H (that is, 3×H). However, the implementation is not limited thereto, and the first through sixth cells C1 through C6 may have different cell heights, and for example, at least one of the first through sixth cells C1 through C6 may correspond to a double-height cell or the triple-height cell.

For example, each of the first through fourth filler cells FC1 through FC4 may correspond to a single-height cell having the first cell height H. However, the implementation is not limited thereto, and the first through fourth filler cells FC1 through FC4 may have different cell heights. For example, at least one of the first through fourth filler cells FC1 through FC4 may have a cell height corresponding to half the first cell height H (that is, about 0.5×H).

The multi-height cell 11 may include active patterns NAP1, NAP2, WAP1, and WAP2 each extending in a first direction X. In this case, each of the active patterns NAP1 and NAP2 may have a first width W1 in a second direction Y, and each of the active patterns WAP1 and WAP2 may have a second width W2 greater than the first width W1 in the second direction Y. In some implementations, the active patterns NAP1 and NAP2 having the first width W1 and included in the multi-height cell 11 may be referred to as first and second normal active patterns NAP1 and NAP2. In addition, in some implementations, the active patterns WAP1 and WAP2 having the second width W2 and included in the multi-height cell 11 may be referred to as first and second wide active patterns WAP1 and WAP2. In some implementations, the “wide active pattern” may be referred to as a “merged active pattern”.

In some implementations, each of the first and second normal active patterns NAP1 and NAP2 may have a first length L1 in the first direction X, and each of the first and second wide active patterns WAP1 and WAP2 may have a second length L2 less than the first length L1 in the first direction X. As described above, the multi-height cell 11 may be implemented as an I-shaped cell. However, in some implementations, the first and second normal active patterns NAP1 and NAP2 and the first and second wide active patterns WAP1 and WAP2 may have the same length in the first direction X, and the multi-height cell 11 may also be implemented as a rectangular cell.

In some implementations, each of the first and second normal active patterns NAP1 and NAP2 may include a normal nanosheet stack. The normal nanosheet stack may include a plurality of normal nanosheets apart from each other in a vertical direction Z, and each of the plurality of normal nanosheets may have the first width W1. In some implementations, each of the first and second wide active patterns WAP1 and WAP2 may include a wide nanosheet stack. The wide nanosheet stack may include a plurality of wide nanosheets apart from each other in the vertical direction Z, and each of the plurality of wide nanosheets may have the second width W2. In some implementations, each of the first and second normal active patterns NAP1 and NAP2, and the first and second wide active patterns WAP1 and WAP2 may also include a fin-shaped active pattern.

A first cell C1 may include active patterns AP1a and AP1b which extend respectively in the first direction X and are apart from each other in the second direction Y. A second cell C2 may include active patterns AP2a and AP2b which extend respectively in the first direction X and are apart from each other in the second direction Y. A third cell C3 may include active patterns AP3a and AP3b which extend respectively in the first direction X and are apart from each other in the second direction Y. A fourth cell C4 may include active patterns AP4a and AP4b which extend respectively in the first direction X and are apart from each other in the second direction Y. A fifth cell C5 may include active patterns AP5a and AP5b which extend respectively in the first direction X and are apart from each other in the second direction Y. A sixth cell C6 may include active patterns AP6a and AP6b which extend respectively in the first direction X and are apart from each other in the second direction Y. Each of the active patterns AP1a, AP1b, AP2a, AP2b, AP3a, AP3b, AP4a, AP4b, AP5a, AP5b, AP6a, and AP6b may have the first width W1 in the second direction Y.

For example, the first normal active pattern NAP1, the second wide active pattern WAP2, and the active patterns AP1a, AP2b, AP3a, AP4a, AP5b, and AP6a may have a first conductivity type. For example, the first conductivity type may include a P-type, and the first normal active pattern NAP1, the second wide active pattern WAP2, and the active patterns AP1a, AP2a, AP3a, AP4a, AP5b, and AP6a may correspond to P-type active patterns AP_P doped with P-type impurities. Accordingly, each of the first normal active pattern NAP1, the second wide active pattern WAP2, and the active patterns AP1a, AP3a, AP4a, AP5b, and AP6a may constitute a P-type transistor, for example, a P-channel metal-oxide-semiconductor (PMOS) transistor. For example, each of the first normal active pattern NAP1, the second wide active pattern WAP2, and the active patterns AP1a, AP3a, AP4a, AP5b, and AP6a may constitute a P-type gate-all-around field effect transistor (GAAFET). For example, each of the first normal active pattern NAP1, the second wide active pattern WAP2, and the active patterns AP1a, AP3a, AP4a, AP5b, and AP6a may constitute a P-type fin field effect transistor (FinFET).

For example, the second normal active pattern NAP2, the first wide active pattern WAP1, and the active patterns AP1b, AP2a, AP3b, AP4b, AP5a, and AP6b may have a second conductivity type. For example, the second conductivity type may include an N-type, and the second normal active pattern NAP2, the first wide active pattern WAP1, and the active patterns AP1b, AP2a, AP3b, AP4b, AP5a, and AP6b may correspond to N-type active patterns AP_N doped with N-type impurities. Accordingly, each of the second normal active pattern NAP2, the first wide active pattern WAP1, and the active patterns AP1b, AP2a, AP3b, AP4b, AP5a, and AP6b may constitute an N-type transistor, for example, an N-channel metal-oxide-semiconductor (NMOS) transistor. For example, the second normal active pattern NAP2, the first wide active pattern WAP1, and the active patterns AP1b, AP2a, AP3b, AP4b, AP5a, and AP6b may constitute an N-type GAAFET. For example, the second normal active pattern NAP2, the first wide active pattern WAP1, and the active patterns AP1b, AP2a, AP3b, AP4b, AP5a, and AP6b may constitute an N-type FinFET.

The integrated circuit 10 may further include a plurality of power rails PR1 through PR4 each extending in the first direction X and apart from each other in the second direction Y. For example, the power rails PR1 and PR3 may receive a first supply voltage, for example, a power supply voltage VDD. For example, the power rails PR2 and PR4 may receive a second supply voltage, for example, a ground voltage VSS. In some implementations, the plurality of power rails PR1 through PR4 may be implemented on a front side wiring layer arranged on a front side or front surface of a substrate on which the integrated circuit 10 is arranged, and accordingly, a front side power delivery network (FSPDN) may be implemented. In some implementations, the plurality of power rails PR1 through PR4 may be implemented on a back side wiring layer arranged on a back side or back surface of the substrate on which the integrated circuit 10 is arranged, and accordingly, a back side power delivery network (BSPDN) may be implemented. In some implementations, the plurality of power rails PR1 through PR4 may be implemented on both the front side wiring layer and the back side wiring layer.

Each of the first through sixth cells C1 through C6 may be defined by a cell boundary BD. An upper boundary or upper end boundary and a lower boundary or lower end boundary of each of the first through sixth cells C1 through C6 may overlap one of the plurality of power rails PR1 through PR4. For example, the upper end boundaries of the first and fourth cells C1 and C4 may overlap the power rail PR1, and the lower end boundaries of the first and fourth cells C1 and C4 may overlap the power rail PR2. For example, the upper end boundary of the multi-height cell 11 may overlap the power rail PR1, and the lower end boundary of the multi-height cell 11 may overlap the power rail PR4.

With the development of semiconductor process technology and the demand for miniaturization of integrated circuits, a cell height of a standard cell is decreasing. As the cell height of the standard cell decreases, a width of an active region and a width of an active pattern inside the standard cell may decrease, and accordingly, a size of a transistor implemented in the standard cell may also decrease. A decrease in the size of the transistor may cause performance degradation of the transistor, and as a result, performance of the standard cell may be deteriorated. Thus, there is a need for a design method capable of maintaining or improving the performance of the standard cell while reducing an area of the standard cell.

In some implementations, the performance of the standard cell may be improved, by merging adjacent active regions or active patterns of the same conductivity type, in a multi-height cell arranged across multi-rows not a single row, for example, in the multi-height cell 11. For example, in the multi-height cell 11, the first wide active pattern WAP1 may be generated by merging adjacent N-type active patterns AP_N, and the second wide active pattern WAP2 may be generated by merging adjacent P-type active patterns AP_P.

In this case, by merging the adjacent N-type active patterns AP_N or the adjacent P-type active patterns AP_P, steps of the active regions or active patterns may occur at the cell boundary point. Because the steps may affect the performance of the adjacent transistor, filler cells, for example, first through fourth filler cells FR1 through FR4 may be arranged at points where the steps occur.

In some examples, the multi-height cell 11 may include the first and second normal active patterns NAP1 and NAP2, and may implement transistors by using the first and second normal active patterns NAP1 and NAP2. Accordingly, filler cells and/or dummy cells may not be disposed in the region where the first and second normal active patterns NAP1 and NAP2 are arranged. Thus, the performance of the integrated circuit 10 may be improved while minimizing the use of filler cells and/or dummy cells.

In addition, in some examples, the multi-height cell 11 may increase the transistor size and in this manner, may improve the performance of the multi-height cell 11, by including the first and second wide active patterns WAP1 and WAP2 that are wider than the active patterns AP1a through AP6b included in the first through sixth cells C1 through C6. In addition, by arranging large-sized vias or contacts on the first and second wide active patterns WAP1 and WAP2, via resistance or contact resistance may be reduced, and in this manner, the performance of the multi-height cell 11 may be furthermore improved.

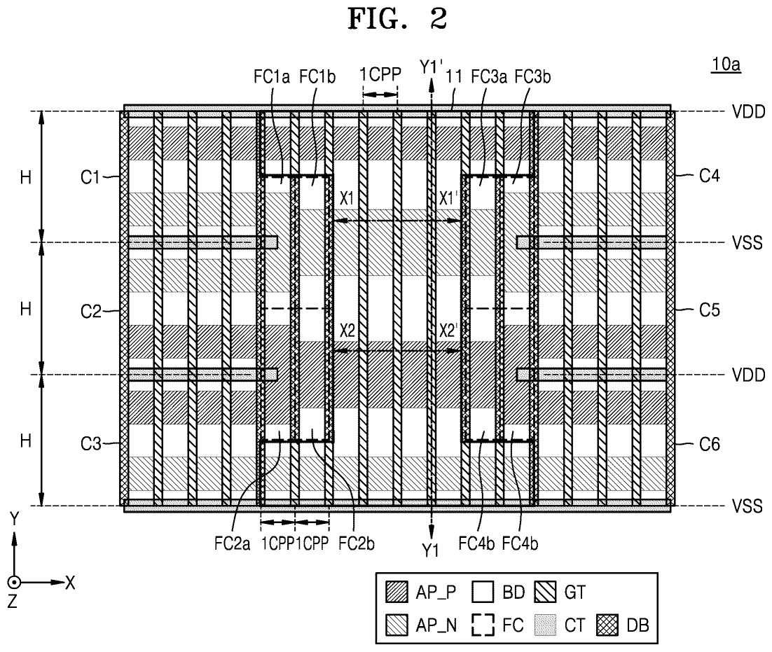

FIG. 2 illustrates a layout of an integrated circuit 10a according to some implementations.

Referring to FIG. 2, the integrated circuit 10a may correspond to the implementation example of the integrated circuit 10 of FIG. 1, and the descriptions given above with reference to FIG. 1 may also be applied to the present implementation. Compared to the integrated circuit 10 of FIG. 1, the integrated circuit 10a may further include a plurality of gate lines GT, a plurality of gate cut lines or gate cut regions CT, and a plurality of separation structures DB. In some implementations, the plurality of separation structures may be referred to as a plurality of active cut lines or active cut regions. In addition, the integrated circuit 10a may include first filler cells FC1a and FC1b adjacent in the first direction X, second filler cells FC2a and FC2b adjacent to each other in the first direction X, third filler cells FC3a and FC3b adjacent to each other in the first direction X, and fourth filler cells FC4a and FC4b adjacent to each other in the first direction X.

The plurality of gate lines GTs may each extend in the second direction Y, and may be apart from each other in the first direction X. For example, the pitch of the plurality of gate lines GT may correspond to a gate pitch, that is, a contacted poly pitch (that is, 1CPP). The plurality of gate lines GTs may be arranged above the P-type active patterns AP_P and the N-type active patterns AP_N in the vertical direction Z. In this case, gate lines overlapping the separation structures DB may correspond to “dummy gate lines”. On the other hand, the gate lines that do not overlap the separation structure DB may correspond to “active gate lines” or “real gate lines”. The active gate lines may implement an active transistor or a real transistor.

The first normal active pattern NAP1 and the gate line GT on the first normal active pattern NAP1 may constitute a first transistor, and the first wide active pattern WAP1 and the gate line GT on the first wide active pattern WAP1 may constitute a second transistor. For example, the first transistor may correspond to a PMOS transistor, and the second transistor may correspond to an NMOS transistor. In this case, the second width W2 of the first wide active pattern WAP1 may be greater than the first width W1 of the first normal active pattern NAP1, and accordingly, the driving capability or driving strength of the second transistor may be greater than the driving capability or driving strength of the first transistor.

The second wide active pattern WAP2 and the gate line GT on the second wide active pattern WAP2 may form a third transistor, and the second normal active pattern NAP2 and the gate line GT on the second normal active pattern NAP2 may form a fourth transistor. For example, the third transistor may correspond to a PMOS transistor, and the fourth transistor may correspond to an NMOS transistor. In this case, the second width W2 of the second wide active pattern WAP2 may be greater than the first width W1 of the second normal active pattern NAP2, and accordingly, the driving capability or driving strength of the third transistor may be greater than the driving capability or driving strength of the fourth transistor.

Each of the gate cut regions CT may extend in the first direction X, and may overlap an upper end boundary and a lower end boundary of each of the first through sixth cells C1 through C6. The gate cut regions CT may respectively cut the gate lines GT extending in the second direction Y, and accordingly, the gate lines GT of different cells adjacent to each other in the second direction Y may be insulated from each other.

Each of the separation structures DB may extend in the second direction Y, and may overlap a left side boundary and a right side boundary of each of the first through sixth cells C1 through C6, and a left side boundary and a right side boundary of first through fourth filler cells FC1a, FC1b, FC2a, FC2b, FC3a, FC3b, FC4a, and FC4b. The separation structures DB may cut the P-type active patterns AP_P and N-type active patterns AP_N extending in the first direction X, respectively, and accordingly, active patterns of different cells adjacent to each other in the first direction X may be insulated from each other. For example, the pitch of the separation structures DB respectively corresponding to the first through fourth filler cells FC1a through FC4b may correspond to the pitch of the gate lines GT, that is, the contacted poly pitch 1CPP. For example, the separation structures DB may be defined by single diffusion breaks (SDBs). Each of the separation structures DB may overlap a dummy gate line.

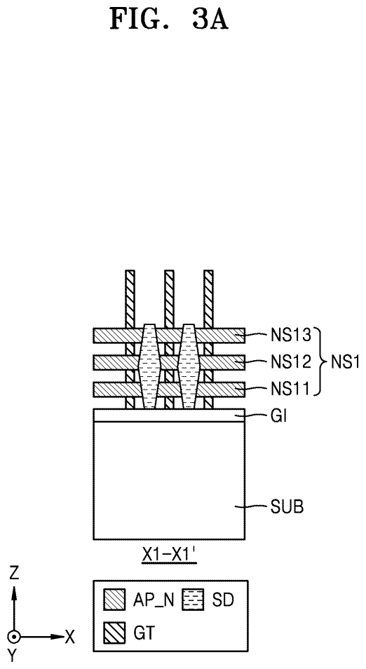

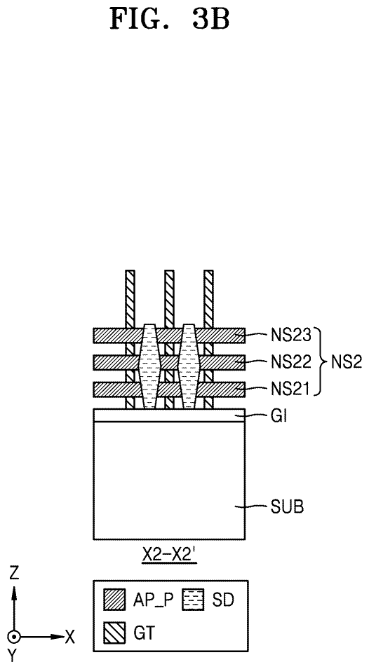

FIG. 3A is an example of a cross-sectional view of the integrated circuit 10a taken along line X1-X1′ in FIG. 2, FIG. 3B is an example of a cross-sectional view thereof taken along line X2-X2′ in FIG. 2, and FIG. 3C is an example of a cross-sectional view thereof taken along line Y1-Y1′ in FIG. 2. FIGS. 3A through 3C illustrate examples in which nanosheets are formed on the active regions. For example, a multi-bridge channel field effect transistor (MBCFET) may be formed in which a plurality of nanosheets are stacked on the active region, and gate lines surround the plurality of nanosheets. However, in some implementations, a GAAFET in which nanowires formed on the active region are surrounded by the gate lines may be formed.

Referring to FIGS. 3A through 3C together, a substrate SUB may include a semiconductor material, such as silicon, germanium, and silicon-germanium, or a Group III-V compound, such as GaAs, AlGaAs, InAs, InGaAs, InSb, InGaSb, InP, GaP, InGaP, InN, GaN, InGaN, and InGaN. For example, the substrate SUB may include a silicon-on-insulator (SOI) substrate or a germanium-on-insulator (GOI) substrate. For example, the substrate SUB may include a P-type substrate doped with P-type impurities.

The active regions may be limited by a device isolation layer (for example, shallow trench isolation (STI)) on the substrate SUB. For example, the active regions may include an N-well doped with N-type impurities, and in this case, a P-type transistor, for example, a P-type GAAFET, may be formed in the N-well. For example, the active regions may include a P-well doped with P-type impurities, and in this case, a P-type transistor, for example, an N-type GAAFET, may be formed in the P-well.

A gate insulating layer GI may be arranged on the substrate SUB. Active patterns, for example, nanosheets, may be formed on the gate insulating layer GI. In this case, the nanosheets may function as channels of transistors. A first nanosheet stack NS1 may correspond to the first wide active pattern WAP1, a second nanosheet stack NS2 may correspond to the second wide active pattern WAP2, a third nanosheet stack NS3 may correspond to the second normal active pattern NAP2, and a fourth nanosheet stack NS4 may correspond to the first normal active pattern NAP1.

The first nanosheet stack NS1 may include nanosheets NS11 through NS13 apart from each other in the vertical direction Z, and each of the nanosheets NS11 through NS13 may have the second width W2 in the second direction Y. The second nanosheet stack NS2 may include nanosheets NS21 through NS23 apart from each other in the vertical direction Z, and each of the nanosheets NS21 through NS23 may have the second width W2 in the second direction Y. The third nanosheet stack NS3 may include nanosheets NS31 through NS33 apart from each other in the vertical direction Z, and each of the nanosheets NS31 through NS33 may have the first width W1 in the second direction Y. The fourth nanosheet stack NS4 may include nanosheets NS41 through NS43 spaced apart from each other in the vertical direction Z, and each of the nanosheets NS41 through NS43 may have the first width W1 in the second direction Y.

The gate line GT may cover the first through fourth nanosheet stacks NS1 through NS4 and surround each of the plurality of nanosheets NS11 through NS43. The plurality of nanosheets NS11 through NS43 may have a GAA structure in which the plurality of nanosheets NS11 through NS43 are surrounded by the gate line GT. A gate insulating layer may be arranged between the plurality of nanosheets NS11 through NS43 and the gate line GT. The gate line GT may be defined as conductive segments including a conductive material, such as polysilicon and one or more metals.

Source/drains SD may be arranged on both sides of the gate line GT, and accordingly, a source and a drain may be apart from each other in the first direction X. The source/drains SD may be arranged on the active regions, respectively. For example, the source/drains SD may be in contact with the plurality of nanosheets NS11 through NS13 of the first nanosheet stack NS1, and may be arranged to cover side surfaces of each of the plurality of nanosheets NS11 through NS13. For example, the source/drains SD may be in contact with the plurality of nanosheets NS21 through NS23 of the second nanosheet stack NS2, and may be arranged to cover side surfaces of each of the plurality of nanosheets NS21 through NS23.

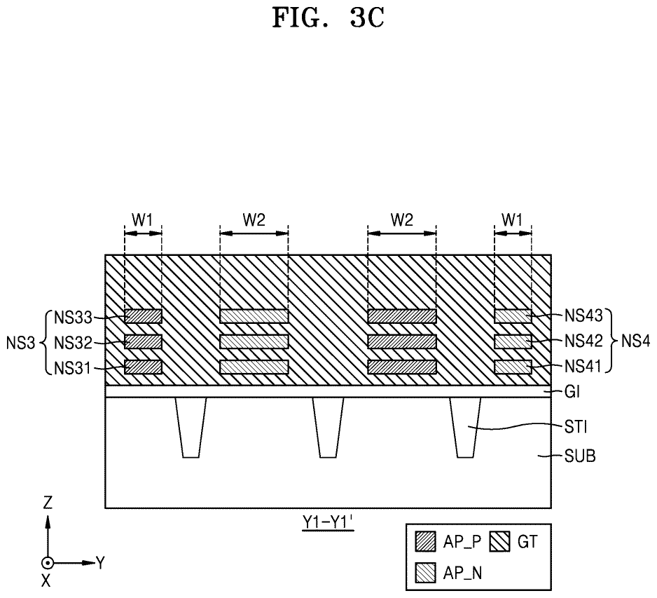

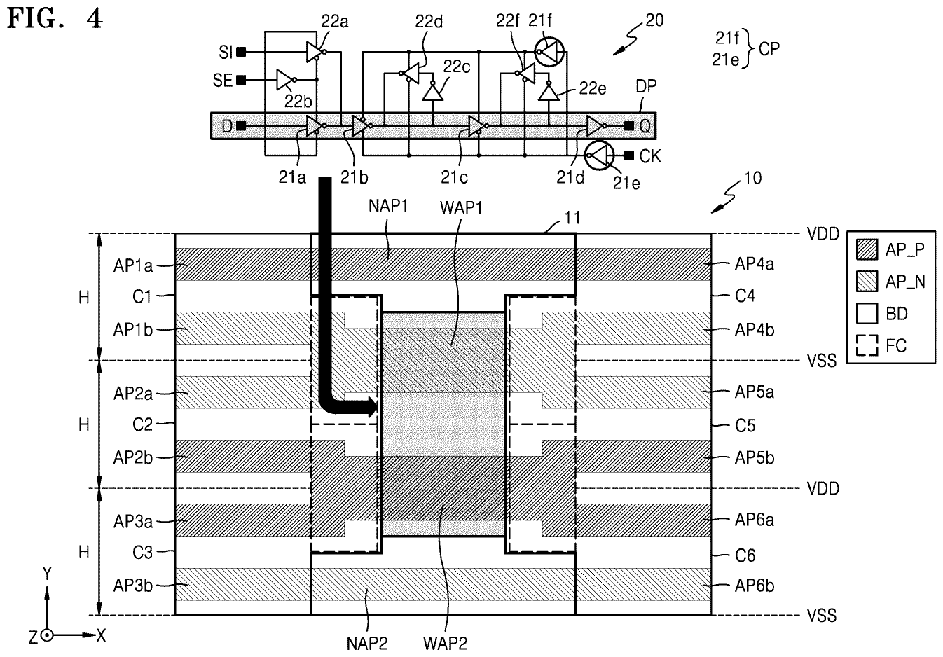

FIG. 4 is a block diagram of an integrated circuit 20 according to some implementations.

Referring to FIG. 4, the integrated circuit 20 may correspond to scan flip-flops including a plurality of inverters 21a through 22f. The inverter 21a may receive a data signal D, the inverter 22a may receive a scan input signal SI, and the inverter 22b may receive a scan enable signal SE. The data signal D or the scan input signal SI may be selected according to the scan enable signal SE. The inverter 21e may receive a clock signal CK, and the inverter 21f may receive an output signal of the inverter 21e, for example, an inverted clock signal. The inverters 22c and 22d may constitute a master latch, and the inverters 22e and 22f may constitute a slave latch. In this case, the inverters 21a, 21b, 21c, and 21d may constitute a data path DP through which the data signal D is transmitted, and the inverters 21e and 21f may constitute a clock path CP through which the clock signal CK is transmitted.

Each of the plurality of inverters 21a through 22f may include a plurality of transistors, and the plurality of transistors may be implemented as the multi-height cell 11. In some implementations, the inverters 21a, 21b, 21c, and 21d constituting the data path DP may be implemented by using the first and second wide active patterns WAP1 and WAP2, and the remaining inverters 21e, 21f, and 22a through 22f may be implemented by using the first and second normal active patterns NAP1 and NAP2. In some implementations, the inverters 21a, 21b, 21c, and 21d constituting the data path DP and the inverters 21e and 21f constituting the clock path CP may be implemented by using the first and second wide active patterns WAP1 and WAP2, and the remaining inverters 22a to 22f may be implemented by using the first and second normal active patterns NAP1 and NAP2.

In this manner, in some implementations, the data path DP and/or the clock path CP of the integrated circuit 20 may be implemented with transistors including the first and second wide active patterns WAP1 and WAP2, and a keeper structure or the remaining inverters of the integrated circuit 20 may be implemented with transistors including the first and second normal active patterns NAP1 and NAP2. For example, the N-type transistor included in the inverter 21a may be implemented as the second transistor including the first wide active pattern WAP1, and the P-type transistor included in the inverter 21a may be implemented as the third transistor including the second wide active pattern WAP2. For example, the P-type transistor included in the inverter 22a may be implemented as the first transistor including the first normal active pattern NAP1, and the N-type transistor included in the inverter 22b may be implemented as the fourth transistor including the second normal active pattern NAP2.

In this case, the driving capability or driving strength of the second and third transistors respectively including the first and second wide active patterns WAP1 and WAP2 may be greater than the driving capability or driving strength of the first and fourth transistors respectively including the first and second normal active patterns NAP1 and NAP2. In this manner, devices constituting the data path DP and/or the clock path CP requiring high reliability may be implemented as transistors having high driving capability or driving strength. Accordingly, performance of the multi-height cell 11 may be improved even at a low voltage condition.

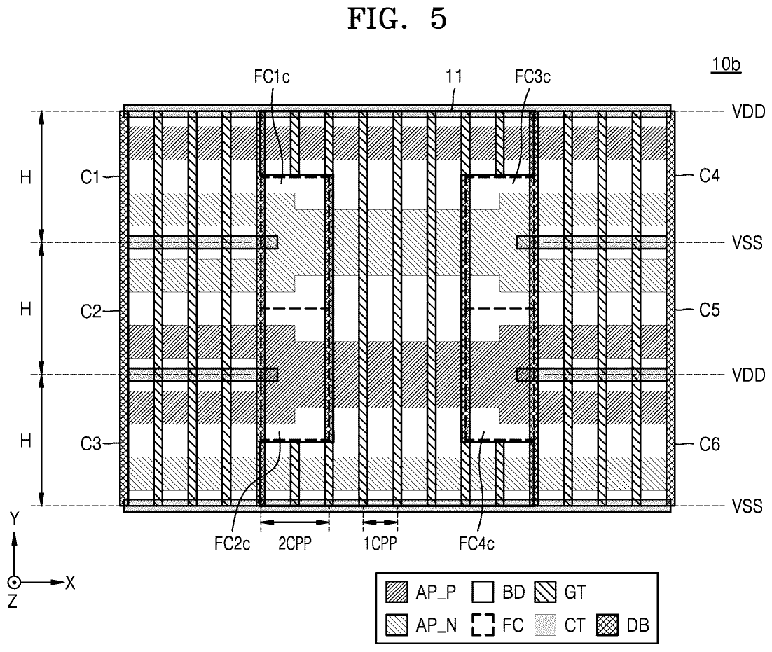

FIG. 5 illustrates a layout of an integrated circuit 10b according to some implementations.

Referring to FIG. 5, the integrated circuit 10b may correspond to a modified example of the integrated circuit 10a of FIG. 1, and the descriptions given with reference to FIGS. 1 through 4 may also be applied to the present implementation. The integrated circuit 10b may include first through fourth filler cells FC1c through FC4c. Each of the separation structures DB may extend in the second direction Y, and may overlap the left side boundary and the right-side boundary of the first through sixth cells C1 through C6, and a left side boundary and a right-side boundary of the first through fourth filler cells FC1c through FC4c. The separation structures DB may cut the P-type active patterns AP_P and N-type active patterns AP_N extending in the first direction X, respectively, and accordingly, active patterns of different cells adjacent to each other in the first direction X may be insulated from each other. For example, the pitch of the separation structures DB respectively corresponding to the first through fourth filler cells FC1c through FC4c may correspond to two times the pitch of the gate lines GT (that is, 2CPP). For example, the separation structures DB may be defined by double diffusion breaks (DDBs).

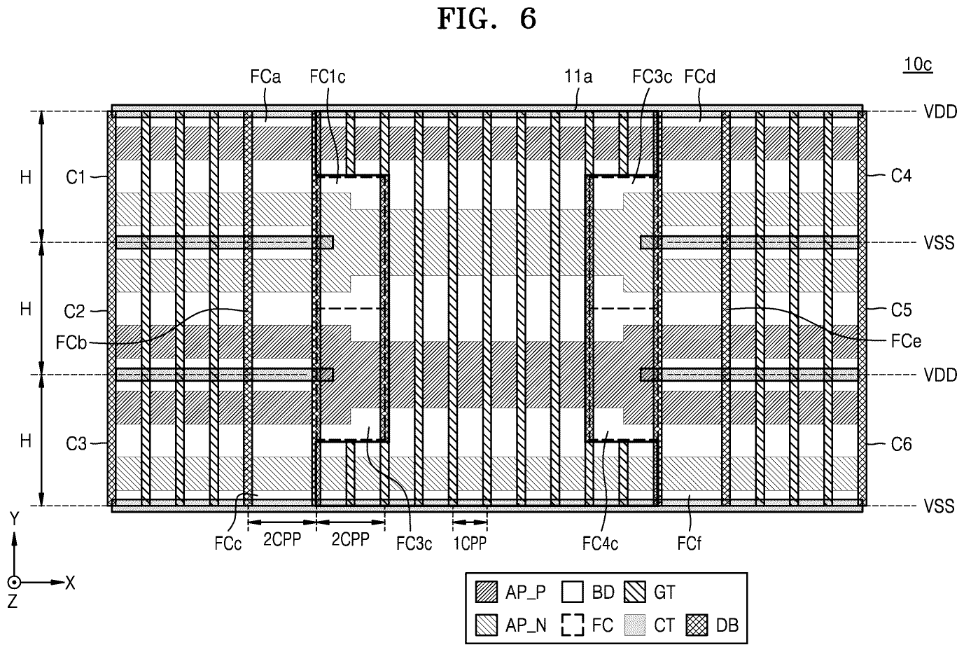

FIG. 6 is a layout of an integrated circuit 10c according to some implementations.

Referring to FIG. 6, the integrated circuit 10c may correspond to a modified example of the integrated circuit 10b of FIG. 5, and the descriptions given with reference to FIGS. 1 through 5 may also be applied to the present implementation. The integrated circuit 10c may include a multi-height cell 11a, the first through fourth filler cells FC1c through FC4c, and additional filler cells FCa through FCf. For example, an area of the multi-height cell 11a may be greater than an area of the multi-height cell 11 of FIG. 5.

Each of the separation structures DB may overlap the left side boundary and the right-side boundary of the first through sixth cells C1 through C6, the left side boundary and the right-side boundary of the first through fourth filler cells FC1c through FC4c, and a left side boundary and a right-side boundary of the additional filler cells FCa through FCf. The separation structures DB may cut the P-type active patterns AP_P and N-type active patterns AP_N extending in the first direction X, respectively, and accordingly, active patterns of different cells adjacent to each other in the first direction X may be insulated from each other. For example, the pitch of the separation structures DB corresponding to the first through fourth filler cells FC1c through FC4c and the additional filler cells FCa through FCf may correspond to two time the pitch of the gate lines GT (that is, 2CPP). For example, the separation structures DB may be defined by the DDBs.

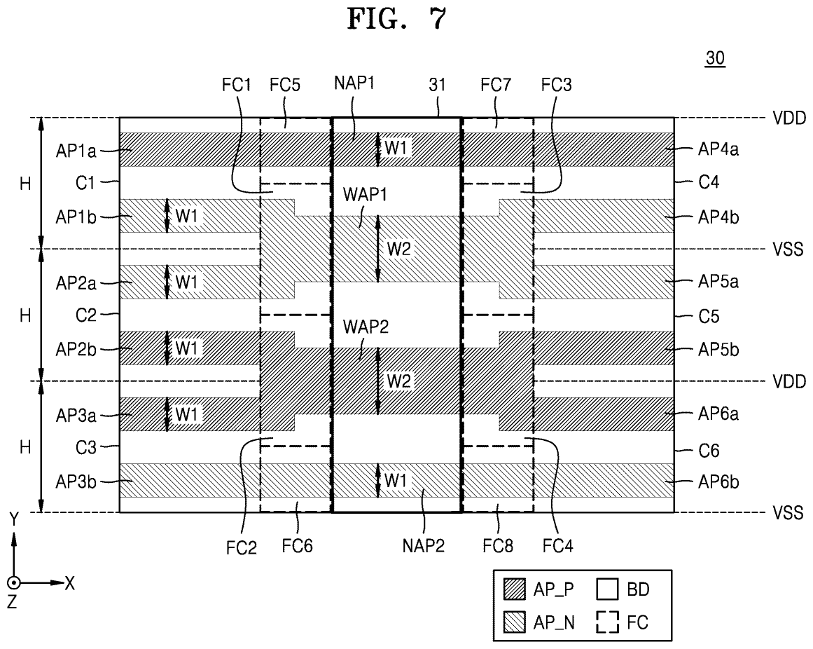

FIG. 7 is a layout of an integrated circuit 30 according to some implementations.

Referring to FIG. 7, the integrated circuit 30 may include a multi-height cell 31, the plurality of cells, for example, first through sixth cells C1 through C6, and a plurality of filler cells, for example, first through eighth filler cells FC1 through FC8. The first, second, fifth, and sixth filler cells FC1, FC2, FC5, and FC6 may be placed or arranged between the first through third cells C1 through C3 and the multi-height cell 31, and the third, fourth, seventh, and eighth filler cells FC3, FC4, FC7, and FC8 may be placed or arranged between the multi-height cell 31 and the fourth through sixth cells C4 through C6. The integrated circuit 30 according to some implementations may correspond to a modified example of the integrated circuit 10 of FIG. 1, and hereinafter, differences from the integrated circuit 10 of FIG. 1 are mainly described. The multi-height cell 31 according to some implementations may be implemented as a rectangular cell.

For example, each of the first through fourth filler cells FC1 through FC4 may correspond to a single-height cell having the first cell height H. For example, each of the fifth through eighth filler cells FC5 through FC8 may have a cell height corresponding to half the first cell height H (that is, about 0.5×H). Accordingly, the first, second, fifth and sixth filler cells FC1, FC2, FC5, and FC6 may be placed or arranged over three rows, and the overall height of the first, second, fifth and sixth filler cells FC1, FC2, FC5, and FC6 may correspond to the cell height of the multi-height cell 31. Similarly, the third, fourth, seventh, and eighth filler cells FC3, FC4, FC7, and FC8 may be placed or arranged over three rows, and the overall height of the third, fourth, seventh, and eighth filler cells FC3, FC4, FC7, and FC8 may correspond to the cell height of the multi-height cell 31.

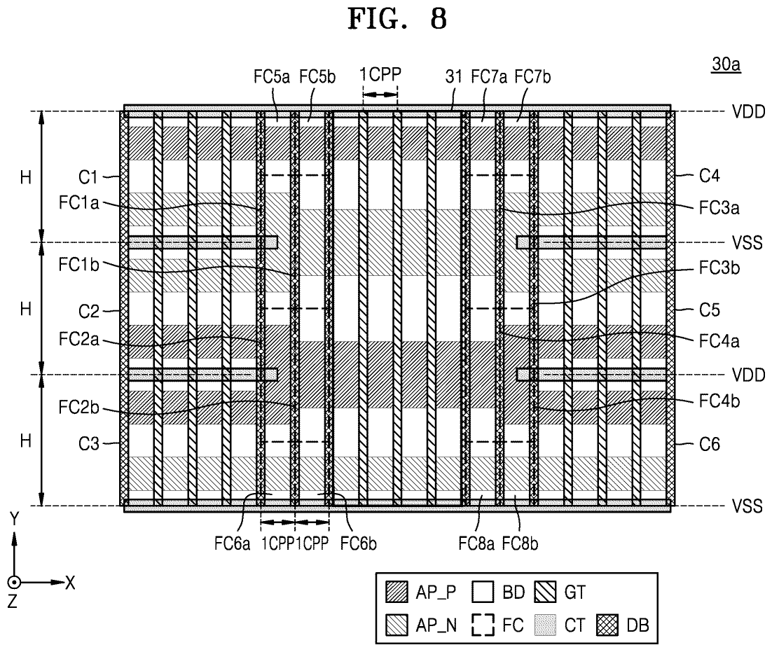

FIG. 8 is a layout of an integrated circuit 30a according to some implementations.

Referring to FIG. 8, the integrated circuit 30a may correspond to the implementation example of the integrated circuit 30 of FIG. 7, and the descriptions given above with reference to FIG. 7 may also be applied to the present implementation. Compared to the integrated circuit 30 of FIG. 7, the integrated circuit 30a may further include the plurality of gate lines GT, a plurality of gate cut lines or the gate cut regions CT, and the plurality of separation structures DB. In addition, the integrated circuit 30a may include first through fourth filler cells FC1a through FC4b, fifth filler cells FC5a and FC5b adjacent to each other in the first direction X, sixth filler cells FC6a and FC6b adjacent to each other in the first direction X, seventh filler cells FC7a and FC7b adjacent to each other in the first direction X, and eighth filler cells FC8a and FC8b adjacent to each other in the first direction X. In this manner, the integrated circuit 30a may further include the fifth through eighth filler cells FC5a through FC8b compared to the integrated circuit 10a of FIG. 2, and hereinafter, differences from the integrated circuit 10a of FIG. 2 are mainly described.

Each of the separation structures DB may extend in the second direction Y, and may overlap the left side boundary and the right-side boundary of each of the first through sixth cells C1 through C6, and a left side boundary and a right-side boundary of each of first through eighth filler cells FC1a through FC8b. The separation structures DB may cut the P-type active patterns AP_P and N-type active patterns AP_N extending in the first direction X, respectively, and accordingly, active patterns of different cells adjacent to each other in the first direction X may be insulated from each other. For example, the pitch of the separation structures DB respectively corresponding to the first through eighth filler cells FC1a through FC8b may correspond to the pitch of the gate lines GT (that is, 1CPP). For example, the separation structures DB may be defined by the SDBs.

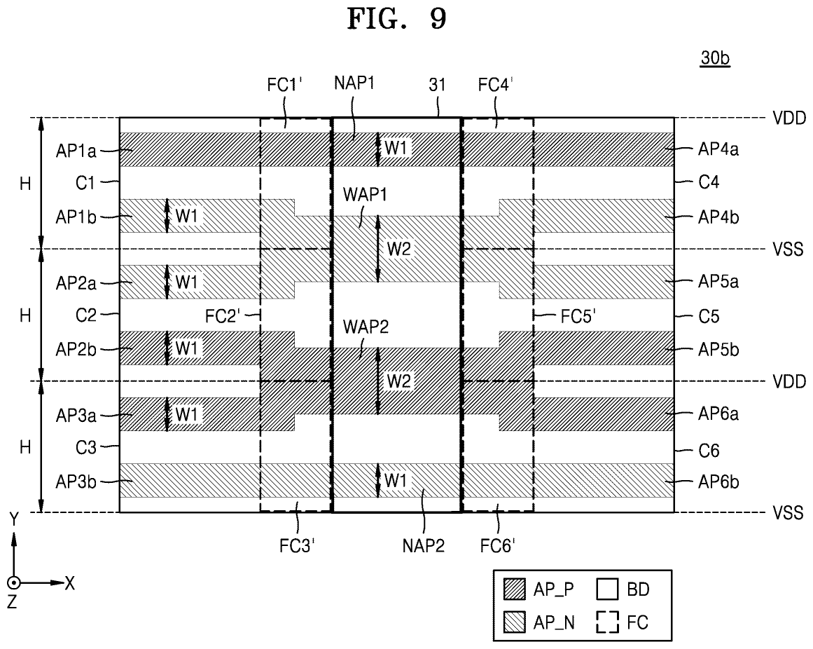

FIG. 9 is a layout of an integrated circuit 30b according to some implementations.

Referring to FIG. 9, the integrated circuit 30b may include the multi-height cell 31, the plurality of cells, for example, first through sixth cells C1 through C6, and a plurality of filler cells, for example, first through sixth filler cells FC1′ through FC6′. The first through third filler cells FC1′ through FC3′ may be placed or arranged between the first through third cells C1 through C3 and the multi-height cell 31, and the fourth through sixth filler cells FC4′ through FC6′ may be placed or arranged between the multi-height cell 31 and the fourth through sixth cells C4 through C6. The integrated circuit 30 according to some implementations may correspond to a modified example of the integrated circuit 30 of FIG. 7, and hereinafter, differences from the integrated circuit 30 of FIG. 7 are mainly described.

For example, each of the first through sixth filler cells FC1′ through FC6′ may correspond to the single-height cell having the first cell height H. Accordingly, the first through third filler cells FC1′ through FC3′ may be placed or arranged over three rows, and the total height of the first through third filler cells FC1′ through FC3′ may correspond to the cell height of the multi-height cell 31. Similarly, the fourth through sixth filler cells FC4′ through FC6′ may be placed or arranged over three rows, and the total height of the fourth through sixth filler cells FC4′ through FC6′ may correspond to the cell height of the multi-height cell 31.

FIG. 10 is a layout of an integrated circuit 30c according to some implementations.

Referring to FIG. 10, the integrated circuit 30c may correspond to the implementation example of the integrated circuit 30b of FIG. 9, and the descriptions given above with reference to FIG. 9 may also be applied to the present implementation. Compared to the integrated circuit 30b of FIG. 9, the integrated circuit 30c may further include the plurality of gate lines GT, the plurality of gate cut lines or the gate cut regions CT, and the plurality of separation structures DB. In addition, the integrated circuit 30c may include first filler cells FC1a′ and FC1b′ adjacent to each other in the first direction X, second filler cells FC2a′ and FC2b′ adjacent to each other in the first direction X, third filler cells FC3a′ and FC3b′ adjacent to each other in the first direction X, fourth filler cells FC4a′ and FC4b′ adjacent to each other in the first direction X, fifth filler cells FC5a′ and FC5b′ adjacent to each other in the first direction X, and sixth filler cells FC6a′ and FC6b′ adjacent to each other in the first direction X.

Each of the separation structures DB may extend in the second direction Y, and may overlap the left side boundary and the right-side boundary of each of the first through sixth cells C1 through C6, and a left side boundary and a right-side boundary of each of the first through sixth filler cells FC1a′ through FC6b′. The separation structures DB may cut the P-type active patterns AP_P and N-type active patterns AP_N extending in the first direction X, respectively, and accordingly, active patterns of different cells adjacent to each other in the first direction X may be insulated from each other. For example, the pitch of the separation structures DB respectively corresponding to the first through sixth filler cells FC1a′ through FC6b′ may correspond to the pitch of the gate lines GT (that is, 1CPP). For example, the separation structures DB may be defined by the SDBs.

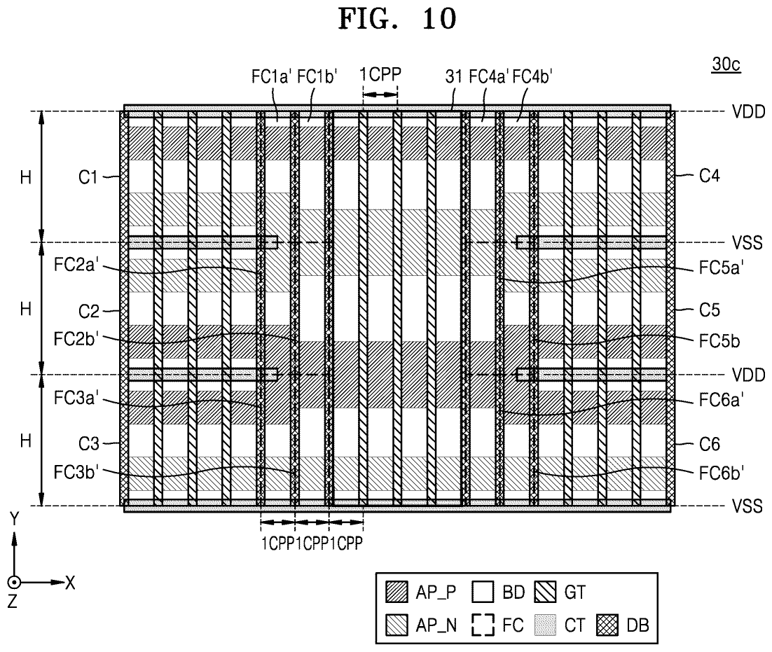

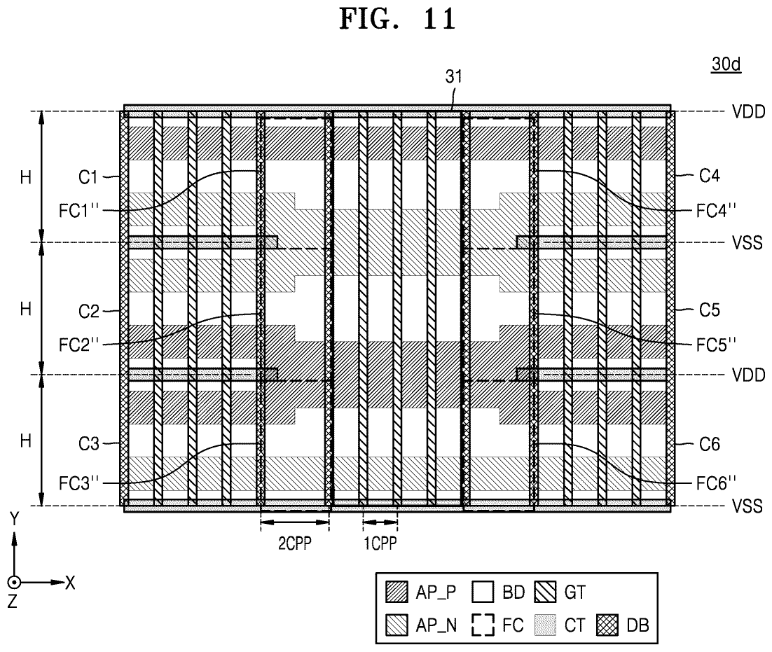

FIG. 11 illustrates a layout of an integrated circuit 30d according to some implementations,

Referring to FIG. 11, the integrated circuit 30d may correspond to the implementation example of the integrated circuit 30c of FIG. 9, and the descriptions given above with reference to FIG. 9 may also be applied to the present implementation. The integrated circuit 30d may include first through sixth filler cells FC1″ through FC6″. Each of the separation structures DB may extend in the second direction Y, and may overlap the left side boundary and the right-side boundary of each of the first through sixth cells C1 through C6, and a left side boundary and a right-side boundary of each of the first through sixth filler cells FC1″ through FC6″. The separation structures DB may cut the P-type active patterns AP_P and N-type active patterns AP_N extending in the first direction X, respectively, and accordingly, active patterns of different cells adjacent to each other in the first direction X may be insulated from each other. For example, the pitch of the separation structures DB respectively corresponding to the first through sixth filler cells FC1″ through FC6″ may correspond to two times the pitch of the gate lines GT (that is, 2CPP). For example, the separation structures DB may be defined by the DDBs.

FIG. 12 is a layout of an integrated circuit 40 according to some implementations.

Referring to FIG. 12, the integrated circuit 40 may include a multi-height cell 41 and a plurality of cells, for example, the first through sixth cells C1 through C6. The multi-height cell 41 may include a filler region FR, and for example, the filler region FR may include a first filler FR1 and a second filler FR2. The integrated circuit 40 may correspond to a modified example of the integrated circuit 10 of FIG. 1, and the descriptions given on with reference to FIGS. 1 through 11 may also be applied to the present implementation.

The multi-height cell 41 may include the first and second normal active patterns NAP1 and NAP2, the first and second wide active patterns WAP1 and WAP2, and the first and second fillers FR1 and FR2. For example, the first filler FR1 may be adjacent to the first through third cells C1 through C3, and overlap transition regions between active patterns AP1b, AP2a, AP2b, and AP3a and the first and second wide active patterns WAP1 and WAP2. For example, the second filler FR2 may be adjacent to the fourth through sixth cells C4 through C6, and overlap transition regions between active patterns AP4b, AP5a, AP5b, and AP6a and the first and second wide active patterns WAP1 and WAP2.

The multi-height cell 41 may further include a plurality of gate electrodes. The plurality of gate electrodes may include a plurality of active gate electrodes and a plurality of dummy gate electrodes. For example, the plurality of active gate electrodes may be arranged on the first and second normal active patterns NAP1 and NAP2 and the first and second wide active patterns WAP1 and WAP2, and may receive a gate voltage from an upper wiring layer via gate contacts. For example, the plurality of dummy gate electrodes may be arranged above the first and second fillers FR1 and FR2, and floated.

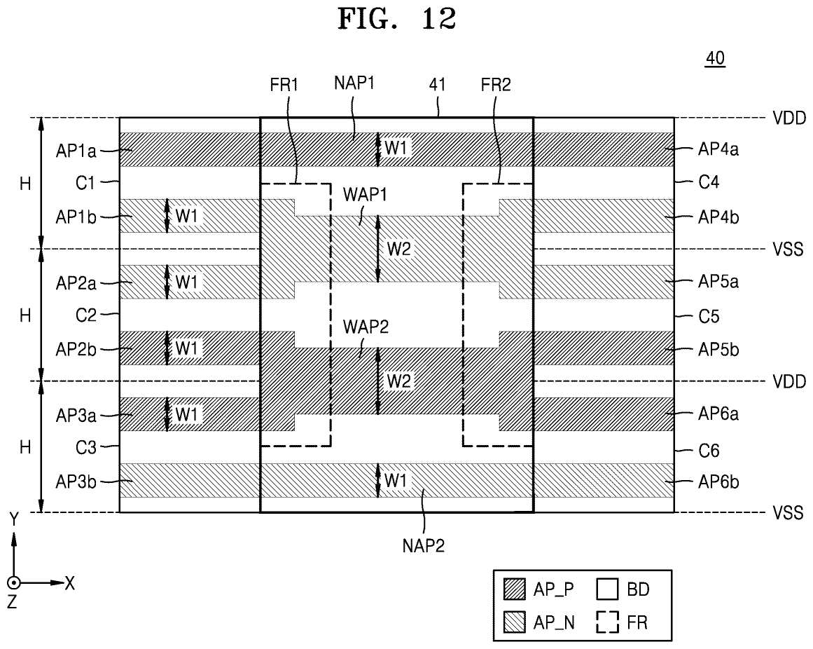

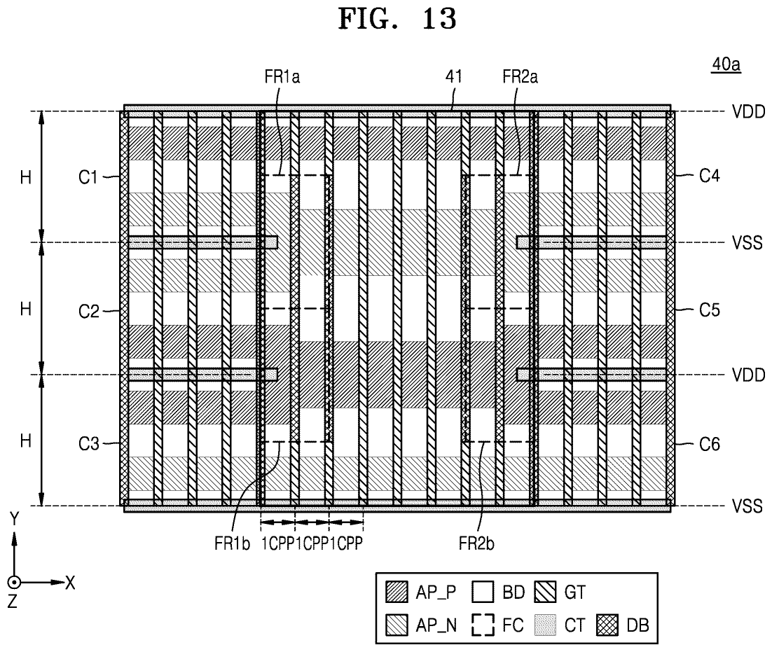

FIG. 13 is a layout of an integrated circuit 40a according to some implementations.

Referring to FIG. 13, the integrated circuit 40a may correspond to the implementation example of the integrated circuit 40 of FIG. 12, and the descriptions given above with reference to FIG. 12 may also be applied to the present implementation. Compared to the integrated circuit 40 of FIG. 12, the integrated circuit 40a may further include the plurality of gate lines GT, the plurality of gate cut lines or the gate cut regions CT, and the plurality of separation structures DB. Each of the first and second fillers FR1 and FR2 may include the separation structures DB arranged at a gate pitch (that is, 1CPP), for example, the single diffusion breaks SDB. The integrated circuit 40a may further include the dummy gate lines, and the first and second fillers FR1 and FR2 may overlap the dummy gate lines. For example, the SDBs may overlap the dummy gate lines.

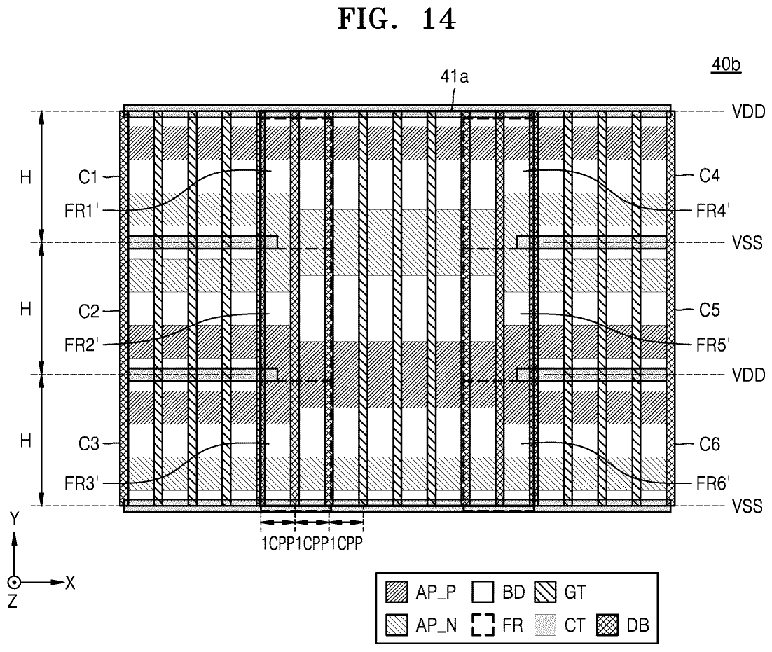

FIG. 14 is a layout of an integrated circuit 40b according to some implementations.

Referring to FIG. 14, the integrated circuit 40b may correspond to a modified example of the integrated circuit 40a of FIG. 13, and may include a multi-height cell 41a and a plurality of cells, for example, the first through sixth cells C1 through C6. The multi-height cell 41a may include first through sixth fillers FR1′ through FR6′. Each of the first through sixth fillers FR1′ through FR6′ may include the separation structures DB arranged at a gate pitch (that is, 1CPP), for example, the SDBs.

FIG. 15 is a layout of an integrated circuit 40c according to some implementations.

Referring to FIG. 15, the integrated circuit 40c may correspond to a modified example of the integrated circuit 40b of FIG. 14, and may include a multi-height cell 41b. The area of the multi-height cell 41b may be greater than the area of the multi-height cell 41a of FIG. 14. For example, the area of the multi-height cell 41b may correspond to the entire area of the multi-height cell 41a and the first and fourth cells C1 and C4 in FIG. 14.

The multi-height cell 41b may include first and second normal active patterns NAP1′ and NAP2′ having the first width W1 in the second direction Y, first and second wide active patterns WAP1′ and WAP2′ having the second width W2 in a second direction Y, and active patterns AP1b through AP6a having the first width W1 in a second direction Y. In this manner, the multi-height cell 41b may be implemented as a large cell and may include more transistors than the multi-height cell 41a.

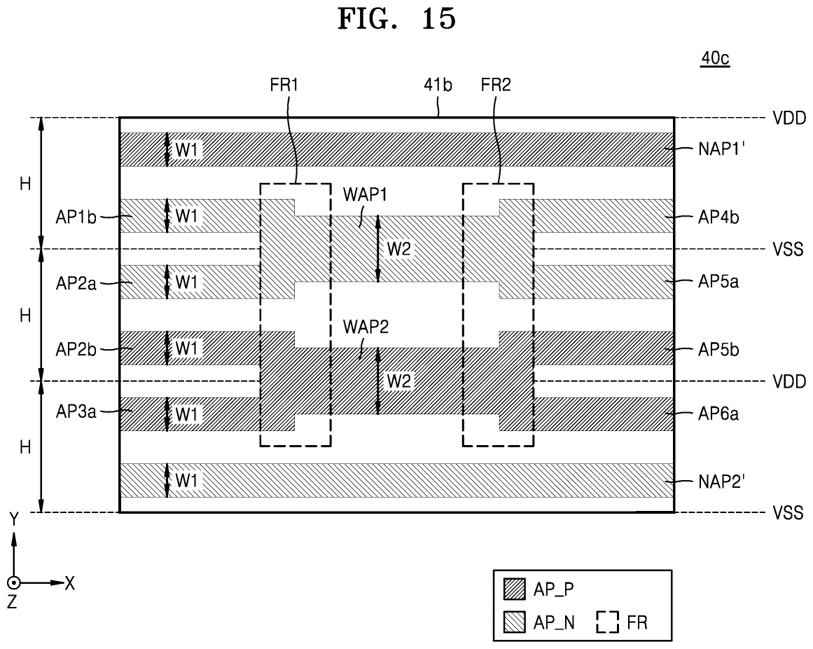

FIG. 16 is a layout of an integrated circuit 50 according to some implementations.

Referring to FIG. 16, the integrated circuit 50 may include a multi-height cell 51 and a plurality of cells, for example, first, second, fourth, and fifth cells C1, C2, C4, and C5. The integrated circuit 50 may correspond to a modified example of the integrated circuit 10 of FIG. 1, and the descriptions given on with reference to FIGS. 1 through 15 may also be applied to the present implementation.

The multi-height cell 51 may be placed or arranged over a plurality of rows, and accordingly, the multi-height cell 51 may have a cell height corresponding to a multiple of the first cell height H (that is, N×H, where N is a natural number greater than 2). For example, each of the first, second, fourth, and fifth cells C1, C2, C4, and C5 may correspond to a single-height cell having the first cell height H, and the multi-height cell 51 may correspond to a double-height cell having a cell height twice the first cell height H (that is, 2×H). However, in some implementations, the first, second, fourth, and fifth cells C1, C2, C4, and C5 may have different cell heights from each other, and for example, at least one of the first, second, fourth, and fifth cells C1, C2, C4, and C5 may correspond to a double height cell.

The multi-height cell 51 may include first and second normal active patterns 511a and 511b and a wide active pattern 512 respectively extending in the first direction X. In t his case, each of the first and second normal active patterns 511a and 511b may have the first width W1 in the second direction Y, and the wide active pattern 512 may have the second width W2 greater than the first width W1 in the second direction Y. For example, the first and second normal active patterns 511a and 511b may respectively correspond to examples of the first and second normal active patterns NAP1 and NAP2 in FIG. 1, and the wide active pattern 512 may correspond to an example of the first wide active pattern WAP1 in FIG. 1.

The first cell C1 may include the active patterns AP1a and AP1b which extend respectively in the first direction X and are apart from each other in the second direction Y. The second cell C2 may include active patterns AP2a and AP2b which extend respectively in the first direction X and are apart from each other in the second direction Y. The fourth cell C4 may include active patterns AP4a and AP4b which extend respectively in the first direction X and are apart from each other in the second direction Y. The fifth cell C5 may include active patterns AP5a and AP5b which extend respectively in the first direction X and are apart from each other in the second direction Y. Each of the active patterns AP1a, AP1b, AP2a, AP2b, AP4a, AP4b, AP5a, and AP5b may have the first width W1 in the second direction Y.

For example, the first and second normal active patterns 511a and 511b and the active patterns AP1a, AP2b, AP4a and AP5b may have a first conductivity type. For example, the first conductivity type may include a P-type, and the first and second normal active patterns 511a and 511b and the active patterns AP1a, AP2b, AP4a and AP5b may correspond to P-type active patterns AP_P doped with P-type impurities. Accordingly, each of the first and second normal active patterns 511a and 511b and the active patterns AP1a, AP2b, AP4a and AP5b may constitute a P-type transistor, for example, a PMOS transistor.

For example, the wide active pattern 512 and the active patterns AP1b, AP2a, AP4b, and AP5a may have a second conductivity type. For example, the second conductivity type may include an N-type, and the wide active pattern 512 and the active patterns AP1b, AP2a, AP4b, and AP5a may correspond to the N-type active patterns AP_N doped with N-type impurities. Accordingly, each of the wide active pattern 512 and the active patterns AP1b, AP2a, AP4b, and AP5a may constitute an N-type transistor, for example, an NMOS transistor.

In an integrated circuit 50′ according to a comparative example, a multi-height cell 51′ may include a wide active pattern WAP, and the wide active pattern WAP may be connected to all of the N-type active patterns AP_N adjacent thereto. In this case, steps may occur between the N-type active patterns AP_N and the wide active pattern WAP, and to solve this issue, the arrangement of fillers or filler cells may be required, and accordingly, an increase in the area of the integrated circuit 50′ may be increased.

However, in some implementations, the wide active pattern 512 of the multi-height cell 51 may be arranged such that upper end edges are aligned with the active patterns AP1b and AP4b adjacent thereto. Accordingly, steps between the wide active pattern 512 and the active patterns AP1b and AP4b adjacent to the wide active pattern 512 may be reduced, and the wide active pattern 512 may not simultaneously be connected to both the active patterns AP1b and AP2a adjacent to the wide active pattern 512, and both the active patterns AP4b and AP5a adjacent to the wide active pattern 512. Therefore, the fillers or filler cells may not be arranged on both sides of the multi-height cell 51, and thus, an increase in the area of the integrated circuit 50 may be prevented.

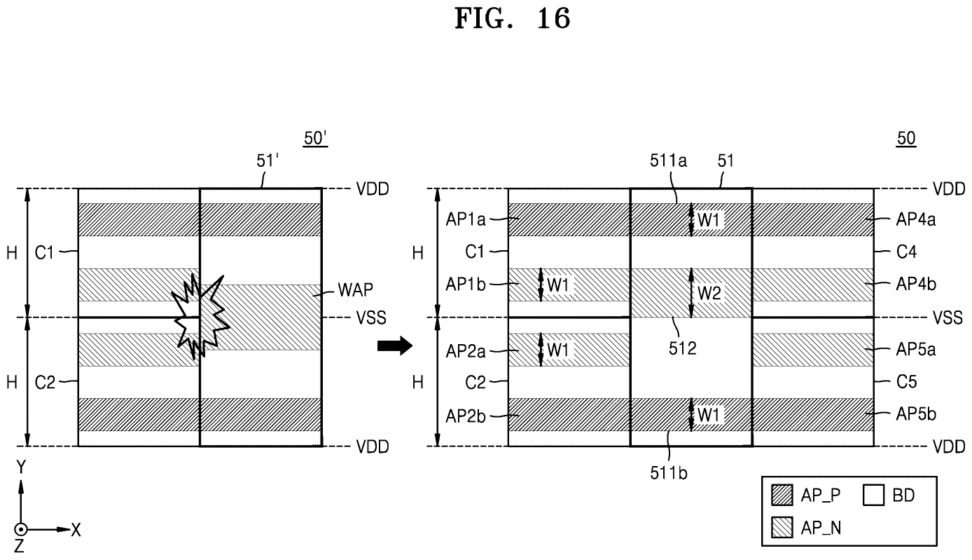

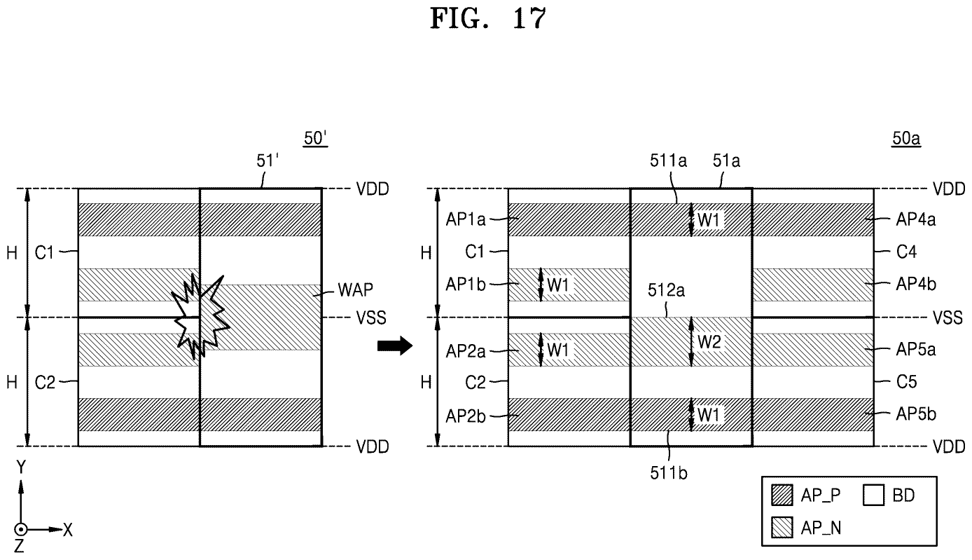

FIG. 17 is a layout of an integrated circuit 50a according to some implementations.

Referring to FIG. 17, the integrated circuit 50a may correspond to a modified example of the integrated circuit 50 of FIG. 16, and hereinafter, the differences from FIG. 16 are mainly described. The integrated circuit 50a may include a multi-height cell 51a, and the multi-height cell 51a may include a wide active pattern 512a. In this case, the wide active pattern 512a may be arranged such that the lower end edges thereof are aligned with the active patterns AP2a and AP5a adjacent thereto. Accordingly, steps between the wide active pattern 512a and the active patterns AP2a and AP5a adjacent to the wide active pattern 512a may be reduced, and the wide active pattern 512a may not simultaneously be connected to both the active patterns AP1b and AP2a adjacent to the wide active pattern 512a, and both the active patterns AP4b and AP5a adjacent to the wide active pattern 512a. Therefore, the fillers or filler cells may not be arranged on both sides of the multi-height cell 51a, and thus, an increase in the area of the integrated circuit 50a may be prevented.

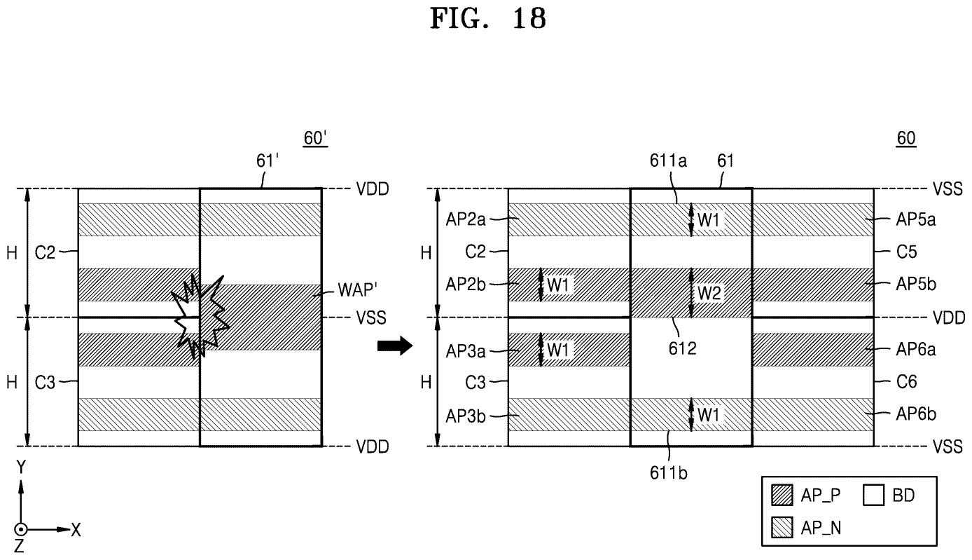

FIG. 18 is a layout of an integrated circuit 60 according to some implementations.

Referring to FIG. 18, the integrated circuit 60 may include a multi-height cell 61 and a plurality of cells, for example, the second, third, fifth, and sixth cells C2, C3, C5, and C6. The integrated circuit 60 may correspond to a modified example of the integrated circuit 10 of FIG. 1, and the descriptions given on with reference to FIGS. 1 through 15 may also be applied to the present implementation.

The multi-height cell 61 may be placed or arranged over a plurality of rows, and accordingly, the multi-height cell 61 may have a cell height corresponding to a multiple of the first cell height H (that is, N×H, where N is a natural number greater than 2). For example, each of the second, third, fifth, and sixth cells C2, C3, C5, and C6 may correspond to a single-height cell having the first cell height H, and the multi-height cell 61 may correspond to a double-height cell having a cell height twice the first cell height H (that is, 2×H). However, in some implementations, the second, third, fifth, and sixth cells C2, C3, C5, and C6 may have different cell heights, and for example, at least one of the second, third, fifth, and sixth cells C2, C3, C5, and C6 may also correspond to a double height cell.

The multi-height cell 61 may include first and second normal active patterns 611a and 611b and a wide active pattern 612 respectively extending in the first direction X. In t his case, each of the first and second normal active patterns 611a and 611b may have the first width W1 in the second direction Y, and the wide active pattern 612 may have the second width W2 greater than the first width W1 in the second direction Y. For example, the first and second normal active patterns 611a and 611b may respectively correspond to examples of the first and second normal active patterns NAP1 and NAP2 in FIG. 1, and the wide active pattern 612 may correspond to an example of the second wide active pattern WAP2 in FIG. 1.

The second cell C2 may include active patterns AP2a and AP2b which extend respectively in the first direction X and are apart from each other in the second direction Y. The third cell C3 may include the active patterns AP3a and AP3b which extend respectively in the first direction X and are apart from each other in the second direction Y. The fifth cell C5 may include active patterns AP5a and AP5b which extend respectively in the first direction X and are apart from each other in the second direction Y. The sixth cell C6 may include active patterns AP6a and AP6b which extend respectively in the first direction X and are apart from each other in the second direction Y. Each of the active patterns AP2a, AP2b, AP3a, AP3b, AP5a, AP5b, AP6a, and AP6b may have the first width W1 in the second direction Y.

For example, the first and second normal active patterns 611a and 611b and the active patterns AP2a, AP3b, AP5a and AP6b may have a second conductivity type. For example, the second conductivity type may include an N-type, and the first and second normal active patterns 611a and 611b and the active patterns AP2a, AP3b, AP5a, and AP6b may correspond to the N-type active patterns AP_N doped with N-type impurities. Accordingly, each of the first and second normal active patterns 611a and 611b and the active patterns AP2a, AP3b, AP5a, and AP6b may constitute an N-type transistor, for example, an NMOS transistor.

For example, the wide active pattern 612 and the active patterns AP2b, AP3a, AP5b, and AP6a may have a first conductivity type. For example, the first conductivity type may include a P-type, and the wide active pattern 612 and the active patterns AP2b, AP3a, AP5b, and AP6a may correspond to the P-type active patterns AP_P doped with P-type impurities. Accordingly, each of the wide active pattern 612 and the active patterns AP2b, AP3a, AP5b, and AP6a may constitute a P-type transistor, for example, a PMOS transistor.

In an integrated circuit 60′ according to a comparative example, a multi-height cell 61′ may include a wide active pattern WAP′, and the wide active pattern WAP may be connected to all of the P-type active patterns AP_P adjacent thereto. In this case, steps may occur between the P-type active patterns AP_P and the wide active pattern WAP′, and to solve this issue, the arrangement of fillers or filler cells may be required, and the area of the integrated circuit 60′ may be increased.

However, in some implementations, the wide active pattern 612 of the multi-height cell 61 may be arranged such that upper end edges of the wide active pattern 612 are aligned with the active patterns AP2b and AP5b adjacent thereto. Accordingly, steps between the wide active pattern 612 and the active patterns AP2b and AP5b adjacent to the wide active pattern 612 may be reduced, and the wide active pattern 612 may not be simultaneously connected to both the active patterns AP2b and AP3a adjacent to the wide active pattern 612. Thus, the fillers or filler cells may not be arranged on both side surfaces of the multi-height cell 61, and therefore, an increase in the area of the integrated circuit 60 may be prevented.

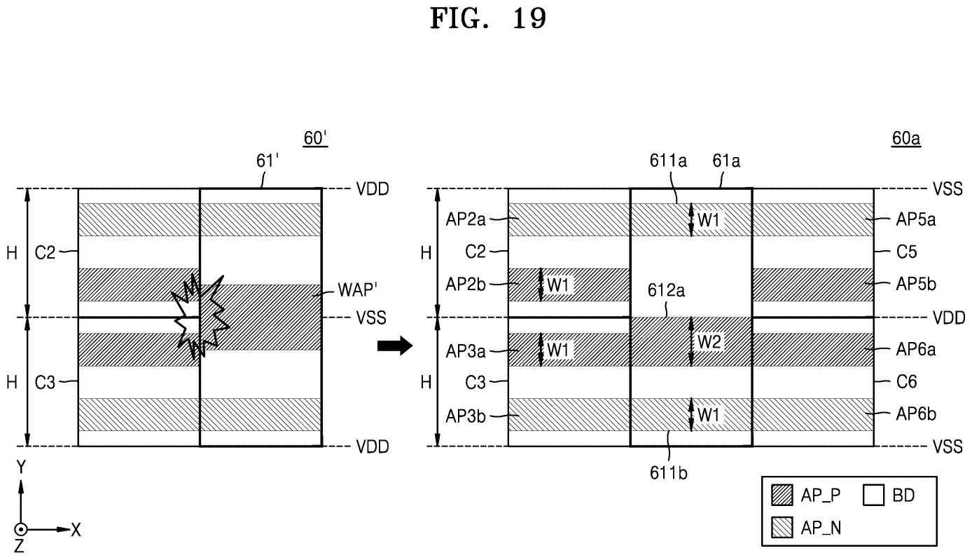

FIG. 19 is a layout of an integrated circuit 60a according to some implementations.

Referring to FIG. 19, the integrated circuit 60a may correspond to a modified example of the integrated circuit 60 of FIG. 18, and hereinafter, the differences from FIG. 18 are mainly described. The integrated circuit 60a may include a multi-height cell 61a, and the multi-height cell 61a may include a wide active pattern 612a. In this case, the wide active pattern 612a may be arranged such that the lower end edges thereof are aligned with the active patterns AP3a and AP6a adjacent thereto. Accordingly, steps between the wide active pattern 612a and the active patterns AP3a and AP6a adjacent to the wide active pattern 612a may be reduced, and the wide active pattern 612a may not be simultaneously connected to both the active patterns AP2b and AP3a adjacent to the wide active pattern 612a. Thus, the fillers or filler cells may not be arranged on both side surfaces of the multi-height cell 61a, and therefore, an increase in the area of the integrated circuit 60a may be prevented.

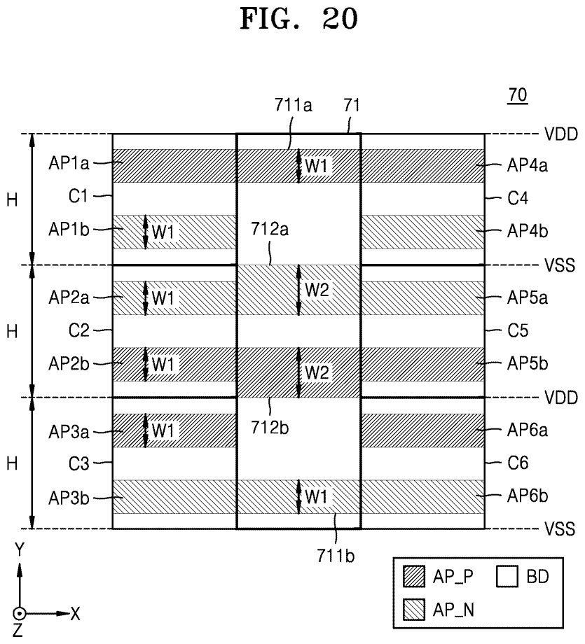

FIG. 20 is a layout of an integrated circuit 70 according to some implementations.

Referring to FIG. 20, the integrated circuit 70 may include a multi-height cell 71 and a plurality of cells, for example, the first through sixth cells C1 through C6. The multi-height cell 71 may include first and second normal active patterns 711a and 711b and first and second wide active patterns 712a and 712b. The integrated circuit 70 may correspond to a modified example of the integrated circuit 10 of FIG. 1, the first and second normal active patterns 711a and 711b may respectively correspond to examples of the first and second normal active patterns NAP1 and NAP2 in FIG. 1, and the first and second wide active patterns 712a and 712b may respectively correspond to examples of the first and second wide active patterns WAP1 and WAP2 in FIG. 1.

In some implementations, the first and second wide active patterns 712a and 712b may be arranged in a center region of the multi-height cell 71. Accordingly, steps between the first and second wide active patterns 712a and 712b and the active patterns AP1b through AP3a and AP4b through AP6a adjacent to the first and second wide active patterns 712a and 712b may be reduced. Thus, the fillers or filler cells may not be arranged on both side surfaces of the multi-height cell 71, and therefore, an increase in the area of the integrated circuit 70 may be prevented.

In some implementations, a lower end edge of a first wide active pattern 712a may be aligned with the lower end edges of adjacent active patterns AP2a and AP5a. Accordingly, steps between the first wide active pattern 712a and the active patterns AP1b and AP2a adjacent to the first wide active pattern 712a may be reduced, and the first wide active pattern 712a may not be simultaneously connected to both the active patterns AP1b and AP2a adjacent to the first wide active pattern 712a. An upper end edge of the first wide active pattern 712a may be apart from lower end edges of the active patterns AP1b and AP4b, and accordingly, the first wide active pattern 712a may not be connected to the active patterns AP1b and AP4b.

In some implementations, an upper end edge of a second wide active pattern 712b may be aligned with upper end edges of the active patterns AP2b and AP5b adjacent to the second wide active pattern 712b. Accordingly, steps between the second wide active pattern 712b and the active patterns AP2b and AP3a adjacent to the second wide active pattern 712b may be reduced, and the second wide active pattern 712b may not be simultaneously connected to both the active patterns AP2b and AP3a adjacent to the second wide active pattern 712b. A lower end edge of the second wide active pattern 712b may be apart from upper end edges of active patterns AP3a and AP6a, and accordingly, the second wide active pattern 712b may not be connected to the active patterns AP3a and AP6a.

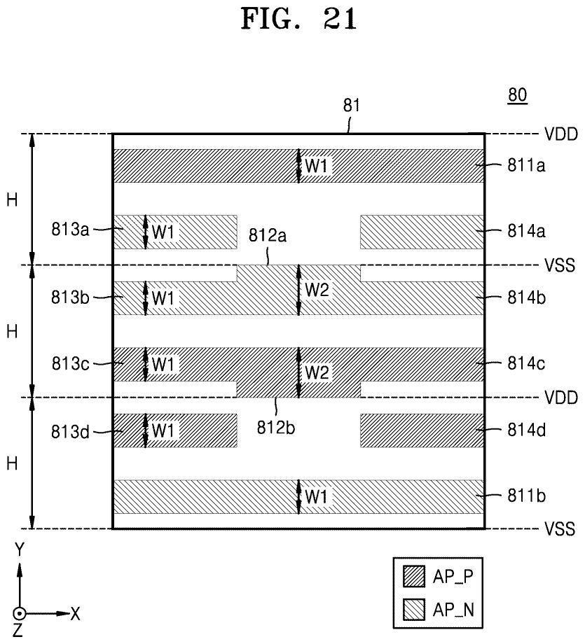

FIG. 21 is a layout of an integrated circuit 80 according to some implementations.

Referring to FIG. 21, the integrated circuit 80 may include a multi-height cell 81, and the multi-height cell 81 may include first and second normal active patterns 811a and 811b, first and second wide active patterns 812a and 812b, and active patterns 813a through 814d. The multi-height cell 81 may correspond to a modified example of the multi-height cell 71 of FIG. 20, and the area of the multi-height cell 81 may be larger than the area of the multi-height cell 71. In some implementations, a plurality of cells may be arranged on both sides of the multi-height cell 81.

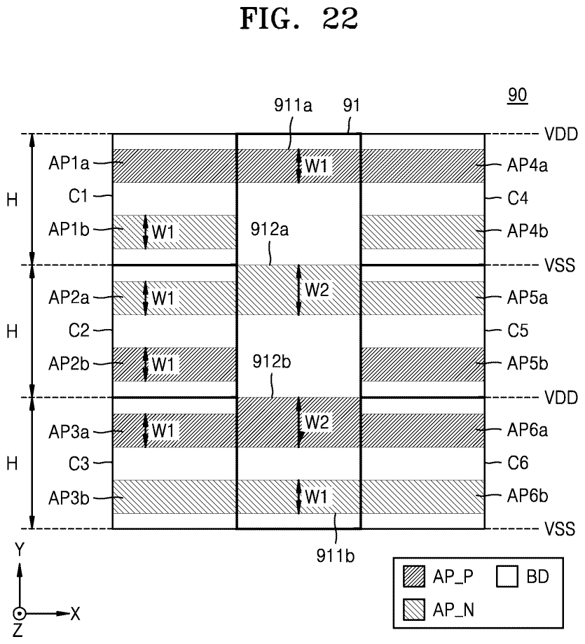

FIG. 22 is a layout of an integrated circuit 90 according to some implementations.

Referring to FIG. 22, the integrated circuit 90 may include a multi-height cell 91 and a plurality of cells, for example, the first through sixth cells C1 through C6. The multi-height cell 91 may include first and second normal active patterns 911a and 911b and first and second wide active patterns 912a and 912b. The integrated circuit 90 may correspond to a modified example of the integrated circuit 10 of FIG. 1, the first and second normal active patterns 911a and 911b may respectively correspond to examples of the first and second normal active patterns NAP1 and NAP2 in FIG. 1, and the first and second wide active patterns 912a and 912b may respectively correspond to examples of the first and second wide active patterns WAP1 and WAP2 in FIG. 1.

In some implementations, the first and second wide active patterns 912a and 912b may be arranged downward in a center region of the multi-height cell 91. Accordingly, steps between the first and second wide active patterns 912a and 912b and the active patterns AP1b through AP3a and AP4b through AP6a adjacent to the first and second wide active patterns 912a and 912b may be reduced. Thus, the fillers or filler cells may not be placed or arranged on both side surfaces of the multi-height cell 91, and therefore, an increase in the area of the integrated circuit 90 may be prevented.

In some implementations, a lower end edge of a first wide active pattern 912a may be aligned with the lower end edges of adjacent active patterns AP2a and AP5a. Accordingly, steps between the first wide active pattern 912a and the active patterns AP1b and AP2a adjacent to the first wide active pattern 912a may be reduced, and the first wide active pattern 712a may not simultaneously connect to both the active patterns AP1b and AP2a adjacent to the first wide active pattern 912a. An upper end edge of the first wide active pattern 912a may be apart from lower end edges of the active patterns AP1b and AP4b, and accordingly, the first wide active pattern 912a may not be connected to the active patterns AP1b and AP4b.

In some implementations, a lower end edge of a second wide active pattern 912b may be aligned with the lower end edges of adjacent active patterns AP3a and AP6a. Accordingly, steps between the second wide active pattern 912b and the active patterns AP2b and AP3a adjacent to the second wide active pattern 912b may be reduced, and the second wide active pattern 912b may not be simultaneously connected to both the active patterns AP2b and AP3a adjacent to the second wide active pattern 912b. An upper end edge of the second wide active pattern 912b may be apart from lower end edges of the active patterns AP2b and AP5b, and accordingly, the second wide active pattern 912b may not be connected to the active patterns AP2b and AP5b.

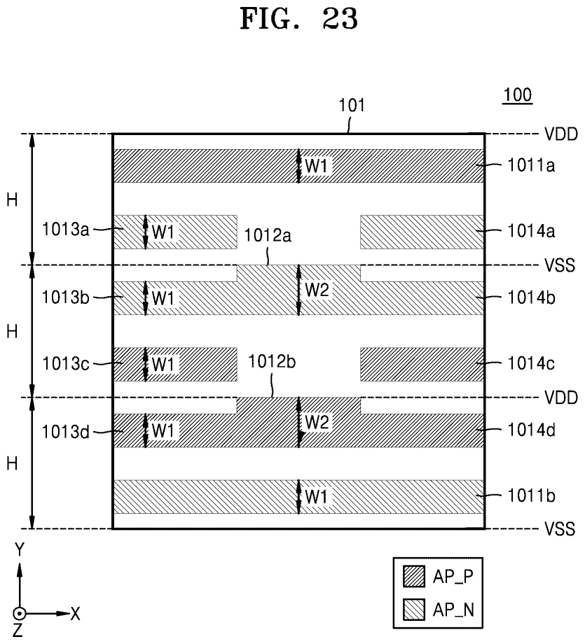

FIG. 23 is a layout of an integrated circuit 100 according to some implementations.

Referring to FIG. 23, the integrated circuit 100 may include a multi-height cell 101, and the multi-height cell 101 may include first and second normal active patterns 1011a and 1011b, first and second wide active patterns 1012a and 1012b, and active patterns 1013 a through 1014d. The multi-height cell 101 may correspond to a modified example of the multi-height cell 91 of FIG. 22, and the area of the multi-height cell 101 may be greater than the area of the multi-height cell 91. In some implementations, a plurality of cells may be arranged on both sides of the multi-height cell 101.

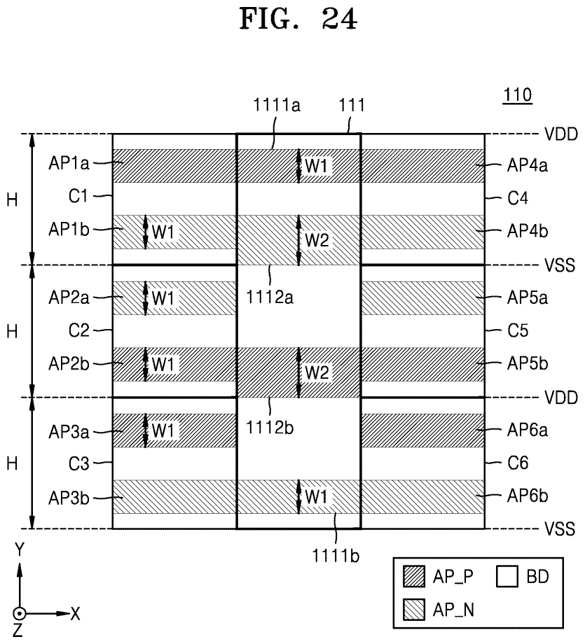

FIG. 24 is a layout of an integrated circuit 110 according to some implementations.

Referring to FIG. 24, the integrated circuit 110 may include a multi-height cell 111 and a plurality of cells, for example, the first through sixth cells C1 through C6. The multi-height cell 111 may include first and second normal active patterns 1111a and 1111b and first and second wide active patterns 1112a and 1112b. The integrated circuit 110 may correspond to a modified example of the integrated circuit 10 of FIG. 1, the first and second normal active patterns 1111a and 1111b may respectively correspond to examples of the first and second normal active patterns NAP1 and NAP2 in FIG. 1, and the first and second wide active patterns 1112a and 1112b may respectively correspond to examples of the first and second wide active patterns WAP1 and WAP2 in FIG. 1.

In some implementations, the first and second wide active patterns 1112a and 1112b may be arranged upward in a center region of the multi-height cell 111. Accordingly, steps between the first and second wide active patterns 1112a and 1112b and the active patterns AP1b through AP3a and AP4b through AP6a adjacent to the first and second wide active patterns 1112a and 1112b may be reduced. Thus, the fillers or filler cells may not be placed or arranged on both side surfaces of the multi-height cell 111, and therefore, an increase in the area of the integrated circuit 110 may be prevented.

In some implementations, an upper end edge of the first wide active pattern 1112a may be aligned with upper end edges of the active patterns AP1b and AP4b adjacent to the first wide active pattern 1112a. Accordingly, steps between the first wide active pattern 1112a and the active patterns AP1b and AP2a adjacent to the first wide active pattern 1112a may be reduced, and the first wide active pattern 1112a may not be simultaneously connected to both the active patterns AP1b and AP2a adjacent to the first wide active pattern 1112a. A lower end edge of the first wide active pattern 1112a may be apart from lower end edges of active patterns AP2a and AP5a, and accordingly, the first wide active pattern 1112a may not be connected to the active patterns AP2a and AP5a.

In some implementations, an upper end edge of a second wide active pattern 1112b may be aligned with upper end edges of the active patterns AP2b and AP5b adjacent to the second wide active pattern 1112b. Accordingly, steps between the second wide active pattern 1112b and the active patterns AP2b and AP3a adjacent to the second wide active pattern 1112b may be reduced, and the second wide active pattern 1112b may not be simultaneously connected to both the active patterns AP2b and AP3a adjacent to the second wide active pattern 1112b. A lower end edge of the second wide active pattern 1112b may be apart from upper end edges of active patterns AP3a and AP6a, and accordingly, the second wide active pattern 1112b may not be connected to the active patterns AP3a and AP6a.

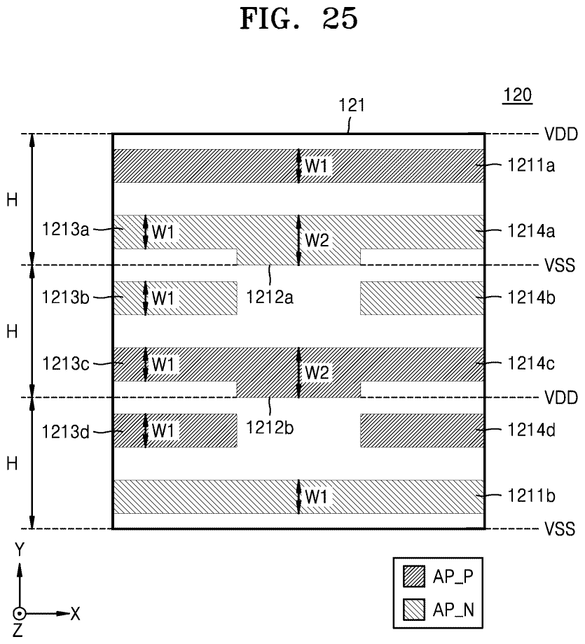

FIG. 25 is a layout of an integrated circuit 120 according to some implementations.

Referring to FIG. 25, the integrated circuit 120 may include a multi-height cell 121, and the multi-height cell 121 may include first and second normal active patterns 1211a and 1211b, first and second wide active patterns 1212a and 1212b, and active patterns 1213 a through 1213d and 1214a through 1214d. The multi-height cell 121 may correspond to a modified example of the multi-height cell 111 of FIG. 24, and the area of the multi-height cell 121 may be greater than the area of the multi-height cell 111. In some implementations, a plurality of cells may be arranged on both sides of the multi-height cell 121.

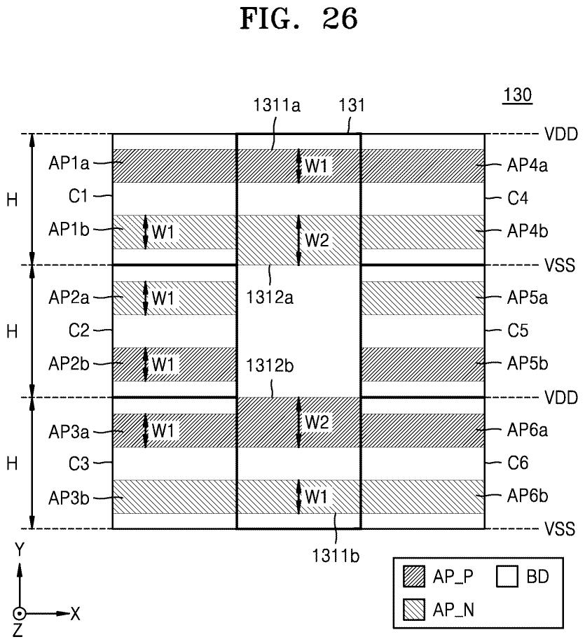

FIG. 26 is a layout of an integrated circuit 130 according to some implementations.

Referring to FIG. 26, the integrated circuit 130 may include a multi-height cell 131 and a plurality of cells, for example, the first through sixth cells C1 through C6. The multi-height cell 131 may include first and second normal active patterns 1311a and 1311b and first and second wide active patterns 1312a and 1312b. The integrated circuit 130 may correspond to a modified example of the integrated circuit 10 of FIG. 1, the first and second normal active patterns 1311a and 1311b may respectively correspond to examples of the first and second normal active patterns NAP1 and NAP2 in FIG. 1, and the first and second wide active patterns 1312a and 1312b may respectively correspond to examples of the first and second wide active patterns WAP1 and WAP2 in FIG. 1.

In some implementations, the first and second wide active patterns 1312a and 1312b may be arranged outward in a center region of the multi-height cell 131. Accordingly, steps between the first and second wide active patterns 1312a and 1312b and the active patterns AP1b through AP3a and AP4b through AP6a adjacent to the first and second wide active patterns 1312a and 1312b may be reduced. Thus, the fillers or filler cells may not be placed or arranged on both side surfaces of the multi-height cell 131, and therefore, an increase in the area of the integrated circuit 130 may be prevented.

In some implementations, an upper end edge of the first wide active pattern 1312a may be aligned with upper end edges of the active patterns AP1b and AP4b adjacent to the first wide active pattern 1312a. Accordingly, steps between the first wide active pattern 1312a and the active patterns AP1b and AP2a adjacent to the first wide active pattern 1312a may be reduced, and the first wide active pattern 1312a may not simultaneously connect to both the active patterns AP1b and AP2a adjacent to the first wide active pattern 1312a. A lower end edge of the first wide active pattern 1312a may be apart from lower end edges of active patterns AP2a and AP5a, and accordingly, the first wide active pattern 1312a may not be connected to the active patterns AP2a and AP5a.

In some implementations, a lower end edge of the second wide active pattern 1312b may be aligned with the lower end edges of adjacent active patterns AP3a and AP6a. Accordingly, steps between the second wide active pattern 1312b and the active patterns AP2b and AP3a adjacent to the second wide active pattern 1312b may be reduced, and the second wide active pattern 1312b may not be simultaneously connected to both the active patterns AP2b and AP3a adjacent to the second wide active pattern 1112b. An upper end edge of the second wide active pattern 1312b may be apart from lower end edges of the active patterns AP2b and AP5b, and accordingly, the second wide active pattern 1312b may not be connected to the active patterns AP2b and AP5b.

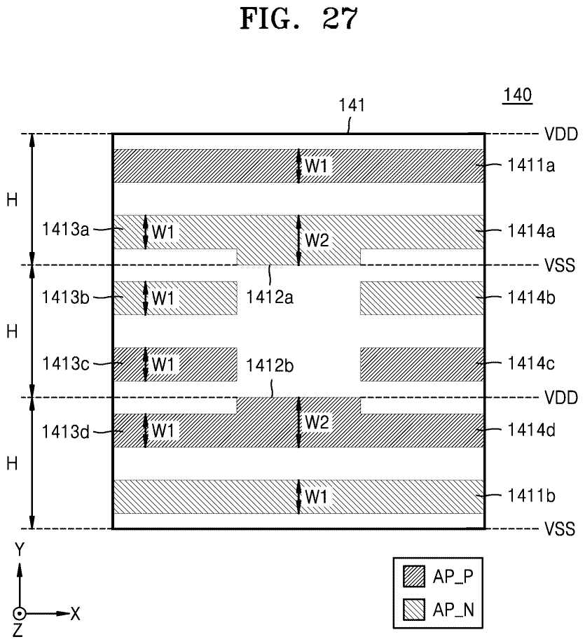

FIG. 27 is a layout of an integrated circuit 140 according to some implementations.

Referring to FIG. 27, the integrated circuit 140 may include a multi-height cell 141, and the multi-height cell 141 may include first and second normal active patterns 1411a and 1411b, first and second wide active patterns 1412a and 1412b, and active patterns 1413 a through 1413d and 1414a through 1414d. The multi-height cell 141 may correspond to a modified example of the multi-height cell 131 of FIG. 26, and the area of the multi-height cell 141 may be greater than the area of the multi-height cell 131. In some implementations, a plurality of cells may be arranged on both sides of the multi-height cell 141.

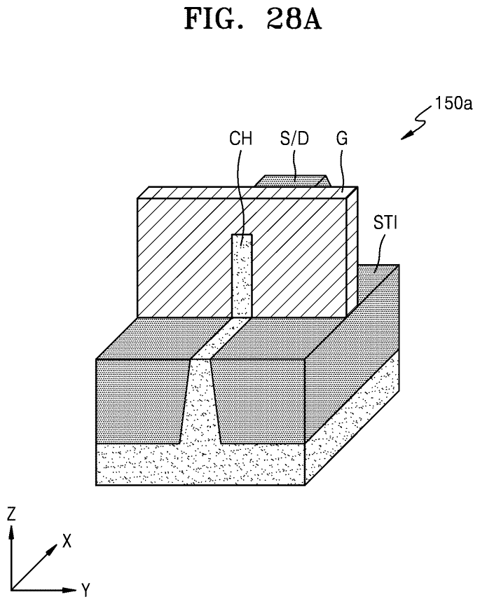

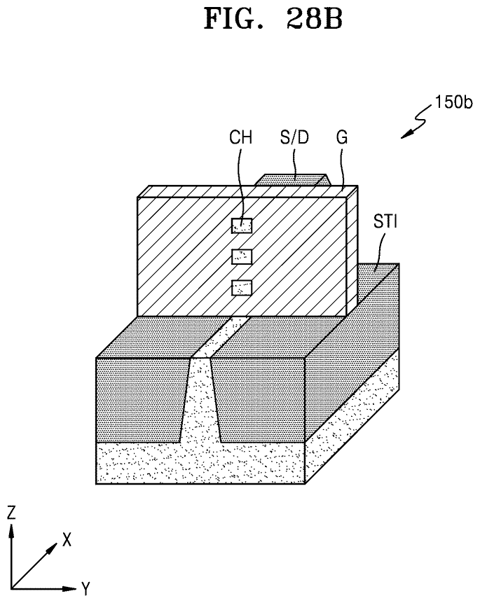

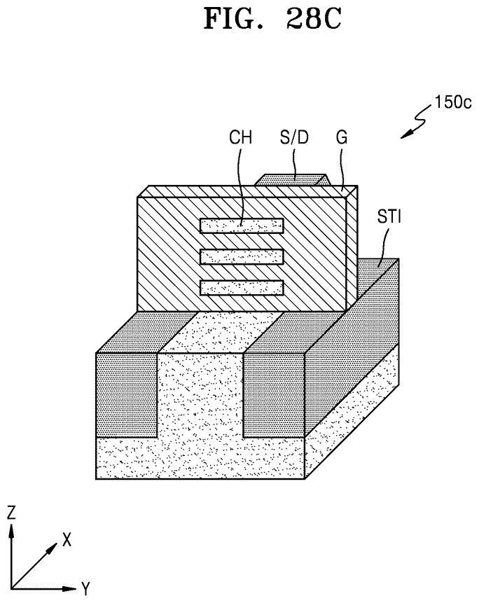

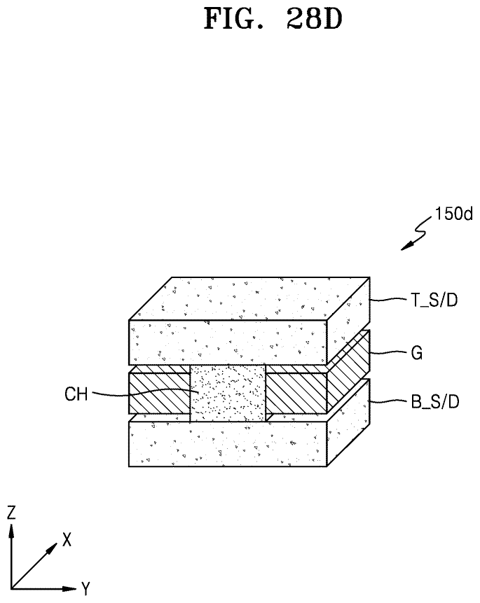

FIGS. 28A through 28D respectively illustrate devices according to some implementations.

For example, FIG. 28A illustrates a FinFET 150a, FIG. 28B illustrates a GAAFET 150b, FIG. 28C illustrates multi-bridge channel FET (MBCFET) 150c, and FIG. 28D illustrates a vertical FET (VFET) 150d. For convenience of illustration, FIGS. 28A through 28C illustrate a state in which one of two source/drain regions is removed, and FIG. 28D illustrates a cross-section of the VFET 150d taken along a plane which is in parallel with a plane extending in the second direction Y and the vertical direction Z and penetrates a channel CH of the VFET 150d.

Referring to FIG. 28A, the FinFET 150a may be formed, between the STIs, by a fin-shaped active pattern extending in the first direction X and a gate G extending in the second direction Y. Source/drains S/D may be formed on both sides of the gate G, and accordingly, the source and the drain may be apart from each other in the first direction X. An insulating layer may be formed between the channel CH and the gate G. In some implementations, the FinFET 150a may be formed by a plurality of active patterns apart from each other in the second direction Y and the gate G.

Referring to FIG. 28B, the GAAFET 150b may be formed by active patterns apart from each other in the vertical direction Z and extending in the first direction X, that is, nanowires, and the gate G extending in the second direction Y. The source/drains S/D may be formed on both sides of the gate G, and accordingly, the source and the drain may be apart from each other in the first direction X. An insulating layer may be formed between the channel CH and the gate G. The number of nanowires included in the GAAFET 150b is not limited to as illustrated in FIG. 28B.

Referring to FIG. 28C, the MBCFET 150c may be formed apart from each other by active patterns in the vertical direction Z and extending in the first direction X, that is, the nanosheets, and the gate G extending in the second direction Y. The source/drains S/D may be formed on both sides of the gate G, and accordingly, the source and the drain may be apart from each other in the first direction X. An insulating layer may be formed between the channel CH and the gate G. The number of nanowires included in the MBCFET 150c is not limited to as illustrated in FIG. 28C.

Referring to FIG. 28D, the VFET 150d may include a top source/drain T_S/D and a bottom source/drain B_S/D apart from each other in the vertical direction Z with the channel CH therebetween. The VFET 150d may include the gate G surrounding the circumference of the channel CH between the top source/drain T_S/D and the bottom source/drain B_S/D. An insulating layer may be formed between the channel CH and the gate G.

In some examples, an integrated circuit may include a plurality of cells, and each cell may include various transistors illustrated in FIGS. 28A through 28D. However, in some implementations, because the nanosheets for a P-type transistor are separated from the nanosheets for an N-type transistor by a dielectric wall, an integrated circuit may include a fork FET (ForkFET) having a structure, in which the N-type transistor and the P-type transistor are further close to each other. In addition, an integrated circuit may also include a FET, such as a complementary (C) FET (CFET), a negative capacitance (NC) (NCFET), and a carbon nanotube (CN) (CNTFET), as well as a bipolar junction transistor.

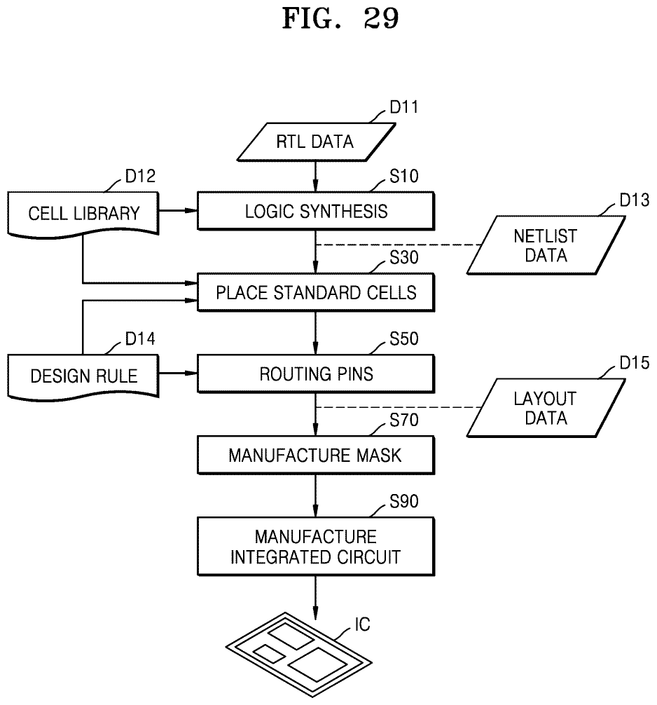

FIG. 29 is a flowchart of a method of manufacturing an integrated circuit, according to some implementations.

Referring to FIG. 29, a method may be a method of manufacturing an integrated circuit (IC) including standard cells, and may include a plurality of operations S10, S30, S50, S70, and S90. A cell library (or standard cell library) D12 may include information about standard cells, such as function information, characteristics information, and layout information. In some implementations, the cell library D12 may define tap cells, filler cells, and dummy cells as well as functional cells generating an output signal from an input signal. For example, the cell library D12 may define the filler cells arranged between standard cells having different metal track structures. Design rule D14 may include requirements to be complied with by the layout of the integrated circuit IC. For example, the design rule D14 may include requirements for the distance between patterns on the same layer, a minimum width of a pattern, a routing direction of a wiring layer, etc. In some implementations, the design rule D14 may define a minimum separation distance on the same track of a wiring layer.

In operation S10, a logic synthesis operation of generating netlist data D13 from register transfer level (RTL) data D11 may be performed. For example, a semiconductor design tool (for example, a logic synthesis tool) may generate the netlist data D13 including a bitstream or a netlist, by performing a logical synthesis with reference to the cell library D12 from the RTL data D11 that is prepared in a hardware description language (HDL), such as very high speed integrated circuit (VHSIC) hardware description language (VHDL) and Verilog. The netlist data D13 may correspond to an input of placement and routing to be described below.

In operation S30, the standard cells may be placed. For example, a semiconductor design tool (for example, a placement and routing (P&R) tool) may place the standard cells used in the netlist data D13 with reference to the cell library D12. In some implementations, a semiconductor design tool may arrange a standard cell in a row extending in the X-axis or Y-axis direction, and the arranged standard cell may receive power from a power rail extending along the boundary of the row.

In operation S50, pins of the standard cells may be routed. For example, a semiconductor design tool may generate interconnections electrically connecting output pins to input pins of the arranged standard cells, and may generate the layout data D15 defining the arranged standard cells and the generated interconnections. The interconnection may include vias of a via layer and/or a pattern of the wiring layer. The wiring layers may include a front side wiring layer arranged above a front side of a substrate and a back side wiring layer arranged on a back side of a substrate. Layout data D15 may have a format such as graphic design system information interchange (GDSII), and may have geometric information about cells and interconnections thereof. A semiconductor design tool may refer to the design rule D14 while routing pins of the cells. The layout data D15 may correspond to an arrangement and an output of routing. Operation S50 alone, or operations S30 and S50 comprehensively may be referred to as a method of designing an integrated circuit.

In some implementations, a multi-height cell may include at least one normal active pattern and at least one wide active pattern, implement a first transistor by using a normal active pattern, and implement a second transistor having high driving capability or high driving strength by using a wide active pattern. Accordingly, filler cells and/or dummy cells may not be placed or arranged in a region where the normal active pattern is arranged. Thus, the performance of the integrated circuit may be improved while minimizing the use of filler cells and/or dummy cells.

In addition, in some implementations, the multi-height cell may increase the transistor size by including at least one wide active pattern wider than active patterns included in cells adjacent to the multi-height cell, and in this manner, the performance of the multi-height cell may be improved. In addition, by arranging large-sized vias or contacts on at least one wide active pattern, via resistance or contact resistance may be reduced, and in this manner, the performance of the multi-height cell 11 may be further improved.

In operation S70, an operation of fabricating a mask may be performed. For example, in photolithography, an optical probability correction (OPC) process for correcting a distortion phenomenon, such as refraction due to characteristics of light, may be applied to the layout data D15. Patterns on the mask may be defined to form patterns arranged on a plurality of layers based on data, to which the OPC has been applied, and at least one mask (or a photomask) for forming patterns of each of the plurality of layers may be manufactured. In some implementations, the layout of the integrated circuit IC may be limitedly modified in operation S70, and the limited modification on the integrated circuit IC in operation S70 may be a post process for optimizing the structure of the integrated circuit IC, which may be referred to as a design polishing process.

In operation S90, an operation of manufacturing the integrated circuit IC may be performed. For example, the integrated circuit IC may be fabricated by patterning the plurality of layers by using at least one mask fabricated in operation S70. A front-end-of-line (FEOL) may include, for example, an operation of flattening and cleaning wafers, an operation of forming trenches, an operation of forming wells, an operation of forming gate lines, and an operation of forming sources and drains. By using the FEOL process, individual devices, for example, a transistor, a capacitor, a resistor, or the like may be formed on a substrate. In addition, a back-end-of-line (BEOL) process may include, for example, silicidating a gate region, a source region, and a drain region, adding a dielectric material, planarizing, forming a hole, adding a metal layer, forming a via, forming a passivation layer, etc. By using the BEOL process, individual devices, for example, a transistor, a capacitor, a resistor, or the like may be interconnected. In some implementations, a middle-of-line (MOL) process may be performed between the FEOL and BEOL processes, and contacts may be formed on individual devices. Next, the integrated circuit IC may be packaged in a semiconductor package, and used as a component of various applications.

The plurality of cells may include first and second cells each having a first cell height, the multi-height cell may correspond to a double-height cell, the at least one normal active pattern may include a first normal active pattern and a second normal active pattern each having a first conductivity type, and the at least one wide active pattern may have a second conductivity type different from the first conductivity type, and include a first wide active pattern arranged between the first normal active pattern and the second normal active pattern.

The first cell may include a first active pattern having the first conductivity type and aligned with the first normal active pattern, and a second active pattern apart from the first active pattern in the second direction, and having the second conductivity type, the second cell may include a third active pattern apart from the second active pattern in the second direction, and having the second conductivity type, and a fourth active pattern apart from the third active pattern in the second direction, having the first conductivity type, and aligned with the second normal active pattern, and an upper end edge of the first wide active pattern may be aligned with an upper end edge of the second active pattern.

The first cell may include a first active pattern having the first conductivity type and aligned with the first normal active pattern, and a second active pattern apart from the first active pattern in the second direction, and having the second conductivity type, the second cell may include a third active pattern apart from the second active pattern in the second direction, and having the second conductivity type, and a fourth active pattern apart from the third active pattern in the second direction, having the first conductivity type, and aligned with the second normal active pattern, and a lower end edge of the first wide active pattern may be aligned with a lower end edge of the third active pattern.

The plurality of cells may include first through third cells each having a first cell height, the multi-height cell may correspond to a triple-height cell, the at least one normal active pattern may include a first normal active pattern having a first conductivity type, and a second normal active pattern having a second conductivity type different from the first conductivity type, and the at least one wide active pattern may include a first wide active pattern having the second conductivity type and apart from the first normal active pattern in the second direction, and a second wide active pattern having the first conductivity type, and arranged between the first wide active pattern and the second normal active pattern.

The first cell may include a first active pattern having the first conductivity type, and aligned with the first normal active pattern, and a second active pattern apart from the first active pattern in the second direction, and having the second conductivity type, the second cell may include a third active pattern apart from the second active pattern in the second direction, and having the second conductivity type, and a fourth active pattern apart from the third active pattern in the second direction, and having the first conductivity type, and the third cell may include a fifth active pattern apart from the fourth active pattern in the second direction, and having the first conductivity type, and a sixth active pattern apart from the fifth active pattern in the second direction, having the second conductivity type, and aligned with the second normal active pattern.

A lower end edge of the first wide active pattern may be aligned with a lower end edge of the third active pattern, and an upper end edge of the second wide active pattern may be aligned with an upper end edge of the fourth active pattern.

A lower end edge of the first wide active pattern may be aligned with a lower end edge of the third active pattern, and a lower end edge of the second wide active pattern may be aligned with a lower end edge of the fifth active pattern.

An upper end edge of the first wide active pattern may be aligned with an upper end edge of the second active pattern, and an upper end edge of the second wide active pattern may be aligned with an upper end edge of the fourth active pattern.

An upper end edge of the first wide active pattern may be aligned with an upper end edge of the second active pattern, and a lower end edge of the second wide active pattern may be aligned with a lower end edge of the fifth active pattern.

The at least one normal active pattern may include a normal nanosheet stack, the normal nanosheet stack may include a plurality of normal nanosheets apart from each other in a vertical direction, and each having the first width in the second direction, the at least one wide active pattern may include a wide nanosheet stack, and the wide nanosheet stack may include a plurality of wide nanosheets apart from each other in the vertical direction, and each having the second width in the second direction.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the inventive concept has been particularly shown and described with reference to implementations thereof, it will be understood that various change in form and details may be made therein without departing from the spirit and scope of the following claims.

What is claimed is:

1. An integrated circuit comprising:
a multi-height cell including (i) at least one normal active pattern having a first width and (ii) at least one wide active pattern having a second width that is greater than the first width, wherein the at least one normal active pattern and the at least one wide active pattern extend in a first direction;
a plurality of cells adjacent to one another in a second direction crossing the first direction, wherein each of the plurality of cells includes at least one active pattern having the first width; and
at least one filler cell, each of the at least one filler cell being between (i) an adjacent cell of the plurality of cells and (ii) the multi-height cell, in the first direction.

2. The integrated circuit of claim 1,
wherein the multi-height cell comprises at least one gate line extending in the second direction,
wherein the at least one normal active pattern and the at least one gate line define a first transistor,
wherein the at least one wide active pattern and the at least one gate line define a second transistor, and
wherein driving capability of the second transistor is greater than driving capability of the first transistor.

3. The integrated circuit of claim 1,
wherein the plurality of cells comprise a first cell, a second cell, and a third cell, each of the first cell, the second cell, and the third cell having a first cell height,
wherein the multi-height cell corresponds to a triple-height cell,
wherein the at least one normal active pattern comprises:
a first normal active pattern having a first conductivity type, and
a second normal active pattern having a second conductivity type that is different from the first conductivity type, and
wherein the at least one wide active pattern comprises:
a first wide active pattern that has the second conductivity type and that is apart from the first normal active pattern in the second direction, and
a second wide active pattern that has the first conductivity type and that is arranged between the first wide active pattern and the second normal active pattern.

4. The integrated circuit of claim 3,
wherein each of the first normal active pattern and the second normal active pattern has a first length in the first direction, and
wherein each of the first wide active pattern and the second wide active pattern has a second length that is less than the first length in the first direction.

5. The integrated circuit of claim 4, wherein the at least one filler cell comprises:
a first filler cell adjacent to the first cell and the second cell in the first direction, and having the first cell height; and
a second filler cell adjacent to the second cell and the third cell in the first direction, adjacent to the first filler cell in the second direction, and having the first cell height.

6. The integrated circuit of claim 5, wherein each of the first filler cell and the second filler cell comprises at least two filler cells adjacent to one another in the first direction.

7. The integrated circuit of claim 3,
wherein each of the first normal active pattern and the second normal active pattern has a first length in the first direction, and
wherein each of the first wide active pattern and the second wide active pattern has the first length in the first direction.

8. The integrated circuit of claim 7, wherein the at least one filler cell comprises:
a first filler cell having the first cell height;
a second filler cell adjacent to the first filler cell in the second direction, and having the first cell height;
a third filler cell adjacent to the first cell in the first direction, and having a second cell height corresponding to half the first cell height; and
a fourth filler cell adjacent to the third cell in the first direction, and having the second cell height, and
wherein the first and second filler cells are arranged between the third filler cell and the fourth filler cell.

9. The integrated circuit of claim 8, wherein each of the first filler cell, the second filler cell, the third filler cell, and the fourth filler cell comprises at least two filler cells adjacent to one another in the first direction.

10. The integrated circuit of claim 7, wherein the at least one filler cell comprises:
a first filler cell adjacent to the first cell in the first direction, and having the first cell height;
a second filler cell adjacent to the second cell in the first direction, adjacent to the first filler cell in the second direction, and having the first cell height; and
a third filler cell adjacent to the third cell in the first direction, adjacent to the second filler cell in the second direction, and having the first cell height.

11. The integrated circuit of claim 10, wherein each of the first filler cell, the second filler cell, and the third filler cell comprises at least two filler cells adjacent to one another in the first direction.

12. The integrated circuit of claim 1,
wherein the at least one normal active pattern comprises a normal nanosheet stack,
wherein the normal nanosheet stack comprises a plurality of normal nanosheets apart from one another in a vertical direction, each of the plurality of normal nanosheets having the first width in the second direction,
wherein the at least one wide active pattern comprises a wide nanosheet stack, and
wherein the wide nanosheet stack comprises a plurality of wide nanosheets apart from one another in the vertical direction, each of the plurality of wide nanosheets having the second width in the second direction.

13. An integrated circuit comprising:
a multi-height cell,
wherein the multi-height cell comprises:
at least one normal active pattern extending in a first direction, having a first length in the first direction, and having a first width in a second direction crossing the first direction;
at least one wide active pattern extending in the first direction, having a second length that is less than the first length in the first direction, and having a second width that is greater than the first width in the second direction;
at least one gate electrode extending in the second direction above the at least one normal active pattern and the at least one wide active pattern;
at least one dummy gate electrode extending in the second direction; and
a filler overlapping with the at least one dummy gate electrode.

14. The integrated circuit of claim 13, further comprising:
a plurality of cells adjacent to the multi-height cell in the first direction, and adjacent to one another in the second direction,
wherein each of the plurality of cells comprises at least one active pattern having the first width.

15. The integrated circuit of claim 13,
wherein the at least one normal active pattern and the at least one gate electrode define a first transistor,
wherein the at least one wide active pattern and the at least one gate electrode define a second transistor, and
wherein driving capability of the second transistor is greater than driving capability of the first transistor.

16. The integrated circuit of claim 13,
wherein the at least one normal active pattern comprises:
a first normal active pattern having a first conductivity type; and
a second normal active pattern having a second conductivity type that is different from the first conductivity type, and
wherein the at least one wide active pattern comprises:
a first wide active pattern that has the second conductivity type and that is apart from the first normal active pattern in the second direction; and
a second wide active pattern having the first conductivity type, and arranged between the first wide active pattern and the second normal active pattern, and
wherein the filler overlaps with the at least one wide active pattern.

17. The integrated circuit of claim 16,
wherein the multi-height cell further comprises:
a first active pattern and a second active pattern, wherein each of the first active pattern and the second active pattern has the second conductivity type, is apart from each other in the second direction, and has the first width; and
a third active pattern and a fourth active pattern, wherein each of the third active pattern and the fourth active pattern has the first conductivity type, is apart from each other in the second direction, and has the first width, and
wherein the filler is arranged between (i) the first active pattern, the second active pattern, the third active pattern, and the fourth active pattern and (ii) the first wide active pattern and the second wide active pattern.

18. The integrated circuit of claim 13,
wherein the at least one normal active pattern comprises a normal nanosheet stack,
wherein the normal nanosheet stack comprises:
a plurality of normal nanosheets apart from one another in a vertical direction, each of the plurality of normal nanosheets having the first width in the second direction,
wherein the at least one wide active pattern comprises a wide nanosheet stack, and
wherein the wide nanosheet stack comprises:
a plurality of wide nanosheets apart from one another in the vertical direction, each of the plurality of wide nanosheets having the second width in the second direction.

19. An integrated circuit comprising:
a multi-height cell; and
a plurality of cells adjacent to the multi-height cell in a first direction, and adjacent to one another in a second direction crossing the first direction,
wherein the multi-height cell comprises:
at least one normal active pattern extending in the first direction and having a first width, and
at least one wide active pattern extending in the first direction and having a second width that is greater than the first width, and
wherein each of the plurality of cells comprises at least one active pattern extending in the first direction and having the first width.

20. The integrated circuit of claim 19,
wherein the multi-height cell further comprises at least one gate line extending in the second direction,
wherein the at least one normal active pattern and the at least one gate line define a first transistor,
wherein the at least one wide active pattern and the at least one gate line define a second transistor, and
wherein driving capability of the second transistor is greater than driving capability of the first transistor.
